(19) United States
(12) Patent Application Publication
(10) Pub. No.: US 2026/0023138 A1
(43) Pub. Date: Jan. 22, 2026

(54) MAGNETIC SENSOR

(71) Applicant: TDK Corporation, Tokyo (JP)

(72) Inventors: Hidekazu KOJIMA, Tokyo (JP); Hirokazu TAKAHASHI, Tokyo (JP); Takashi SAITO, Tokyo (JP); Satoshi MIURA, Tokyo (JP)

(73) Assignee: TDK Corporation, Tokyo (JP)

(21) Appl. No.: 19/262,809

(22) Filed: Jul. 8, 2025

(30) Foreign Application Priority Data
Jul. 18, 2024 (JP) 2024-115096

(51) Int. Cl. G01R 33/09; G01R 33/02

(52) U.S. Cl. CPC G01R 33/091; G01R 33/0206

(57) ABSTRACT

A magnetic sensor includes at least one MR element, and at least one magnetic field generator configured to generate a bias magnetic field. The at least one magnetic field generator includes a first end portion and a second end portion, and includes a first part including the first end portion and a second part including the second end portion. A thickness of the first part is greater than a thickness of the second part. The at least one MR element includes a third end portion and a fourth end portion, and is disposed so that a distance between the first end portion and the third end portion is smaller than a distance between the second end portion and the fourth end portion.

### CROSS REFERENCE TO RELATED APPLICATIONS

This application claims the benefit of Japanese Priority Patent Application No. 2024-115096 filed on Jul. 18, 2024, the entire contents of which are incorporated herein by reference.

### BACKGROUND

The disclosure relates to a magnetic sensor configured to be capable of applying a bias magnetic field to a magnetoresistive element.

Magnetic sensors have been used for various applications in recent years. Examples of known magnetic sensors include one that uses a spin-valve magnetoresistive element provided on a substrate. The spin-valve magnetoresistive element includes a magnetization pinned layer whose magnetization direction is fixed, a free layer whose magnetization direction is variable depending on the direction of a magnetic field applied thereto, and a gap layer disposed between the magnetization pinned layer and the free layer. Spin-valve magnetoresistive elements provided on a substrate are often configured to be sensitive to magnetic fields in a direction parallel to the surface of the substrate. Thus, such magnetoresistive elements are suitable for detecting magnetic fields that vary in direction in a plane parallel to the surface of the substrate.

On the other hand, some systems including a magnetic sensor are intended to detect a magnetic field including a component in a direction perpendicular to the surface of the substrate by using magnetoresistive elements provided on the substrate. In such a case, the magnetic field including the component in the direction perpendicular to the surface of the substrate can be detected by disposing the magnetoresistive elements on an inclined surface formed on the substrate.

Incidentally, some magnetic sensors include a means for applying a bias magnetic field to the magnetoresistive element. The bias magnetic field is used, for example, to cause the magnetoresistive element to respond linearly to a change in the strength of the target magnetic field, which is the magnetic field to be detected. In a magnetic sensor that uses a spin-valve magnetoresistive element, the bias magnetic field is used also to make the free layer have a single magnetic domain and to orient the magnetization direction of the free layer in a certain direction, when there is no target magnetic field.

JP 2007-157979 A discloses a magnetic sensor in which an X-axis sensor, a Y-axis sensor, and a Z-axis sensor are provided on a substrate. V-shaped channels are formed in a thick film on the substrate. Each of slopes of the channels includes a first slope located on an upper half of the channel and a second slope located on a lower half of the channel and having a steeper angle with respect to a surface of the substrate than the first slope. Giant magnetoresistive elements constituting the Z-axis sensor each include a band-like portion provided along the longitudinal direction of the slope and at a position with good flatness of a center part of the second slope, and a bias magnet portion that applies a bias magnetic field to the band-like portion.

JP 2016-176911 A discloses a magnetic sensor including a magnetoresistive element and two magnetic field generators disposed with the magnetoresistive element interposed therebetween. The magnetic field generators each include an antiferromagnetic layer and a ferromagnetic layer stacked together, and are configured to apply a bias magnetic field to the magnetoresistive element.

In the magnetic field generator such as that disclosed in JP 2016-176911 A, the strength of the bias magnetic field generated by the magnetic field generator can be increased by increasing the volume of the magnetic field generator. However, when an attempt is made to form a magnetic field generator on an inclined surface as in the magnetic sensor as disclosed in JP 2007-157979 A, the volume of the magnetic field generator may be smaller than when the magnetic field generator is formed on a plane. As a result, it may not be possible to apply a bias magnetic field of a sufficient strength to the magnetoresistive element in some cases.

### SUMMARY

A magnetic sensor according to a first aspect of one embodiment of the disclosure includes: at least one magnetoresistive element; and at least one magnetic field generator including a ferromagnetic portion formed of a ferromagnetic material and an antiferromagnetic portion formed of an antiferromagnetic material and exchange-coupled with the ferromagnetic portion, and configured to generate a bias magnetic field to be applied to the at least one magnetoresistive element. The at least one magnetoresistive element and the at least one magnetic field generator are aligned along a first direction, and are disposed so that at least a part of the at least one magnetoresistive element overlaps the at least one magnetic field generator when viewed in the first direction. The at least one magnetic field generator includes a first end portion and a second end portion located at both ends of the at least one magnetic field generator in a second direction intersecting the first direction, and a first surface connecting the first end portion and the second end portion, has a thickness which is a dimension in a direction perpendicular to the first surface, and includes a first part including the first end portion and a second part including the second end portion. In any given cross section intersecting the at least one magnetic field generator and perpendicular to the first direction, the thickness of the first part is greater than the thickness of the second part. The at least one magnetoresistive element includes a third end portion and a fourth end portion located at both ends of the at least one magnetoresistive element in the second direction, and the at least one magnetoresistive element is disposed so that a distance between the first end portion and the third end portion in the second direction is smaller than a distance between the second end portion and the fourth end portion in the second direction.

A magnetic sensor according to a second aspect of one embodiment of the disclosure includes: a substrate including a top surface; a support member disposed on the substrate; at least one magnetoresistive element disposed on the support member; and at least one magnetic field generator that is disposed on the support member, includes a ferromagnetic portion formed of a ferromagnetic material and an antiferromagnetic portion formed of an antiferromagnetic material and exchange-coupled with the ferromagnetic portion, and is configured to generate a bias magnetic field to be applied to the at least one magnetoresistive element. The at least one magnetoresistive element and the at least one magnetic field generator are aligned along a first direction, and are disposed so that at least a part of the at least one magnetoresistive element overlaps the at least one magnetic field generator when viewed in the first direction. The at least one magnetic field generator includes a first end portion and a second end portion located at both ends of the at least one magnetic field generator in a second direction intersecting the first direction. The at least one magnetoresistive element includes a third end portion and a fourth end portion located at both ends of the at least one magnetoresistive element in the second direction. The first end portion is located at a position farther from the top surface than the second end portion. The third end portion is located at a position farther from the top surface than the fourth end portion. The at least one magnetoresistive element is disposed so that a distance between the first end portion and the third end portion in the second direction is smaller than a distance between the second end portion and the fourth end portion in the second direction.

A magnetic sensor according to a third aspect of one embodiment of the disclosure includes: a substrate including a top surface; a support member disposed on the substrate; at least one magnetoresistive element disposed on the support member; and at least one magnetic field generator that is disposed on the support member, includes a ferromagnetic portion formed of a ferromagnetic material and an antiferromagnetic portion formed of an antiferromagnetic material and exchange-coupled with the ferromagnetic portion, and is configured to generate a bias magnetic field to be applied to the at least one magnetoresistive element. The at least one magnetoresistive element and the at least one magnetic field generator are aligned along a first direction, and are disposed so that at least a part of the at least one magnetoresistive element overlaps the at least one magnetic field generator when viewed in the first direction. The support member includes a facing surface that faces the at least one magnetoresistive element and the at least one magnetic field generator. The at least one magnetic field generator includes a first end portion and a second end portion located at both ends of the at least one magnetic field generator in a second direction intersecting the first direction. In any given cross section intersecting the at least one magnetic field generator and perpendicular to the first direction, an inclined angle that the facing surface forms with respect to the top surface is greater at a second position, which is a position on the facing surface closest to the second end portion, than at a first position, which is a position on the facing surface closest to the first end portion. The at least one magnetoresistive element includes a third end portion and a fourth end portion located at both ends of the at least one magnetoresistive element in the second direction, and the at least one magnetoresistive element is disposed so that a distance between the first end portion and the third end portion in the second direction is smaller than a distance between the second end portion and the fourth end portion in the second direction.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device including a magnetic sensor according to a first example embodiment of the disclosure.

FIG. 2 is a side view showing the magnetic sensor device shown in FIG. 1.

FIG. 3 is a functional block diagram showing a configuration of the magnetic sensor device shown in FIG. 1.

FIG. 4 is a circuit diagram showing a circuit configuration of a first detection circuit of the first example embodiment of the disclosure.

FIG. 5 is a circuit diagram showing a circuit configuration of a second detection circuit of the first example embodiment of the disclosure.

FIG. 6 is a plan view showing a part of the magnetic sensor according to the first example embodiment of the disclosure.

FIG. 7 is a cross-sectional view showing a part of a cross section at a position indicated by the 7-7 line in FIG. 6.

FIG. 8 is a cross-sectional view showing a part of a cross section at a position indicated by the 8-8 line in FIG. 6.

FIG. 9 is a plan view showing magnetoresistive elements, magnetic field generators, lower electrodes, and upper electrodes of the first example embodiment of the disclosure.

FIG. 10 is a perspective view showing the magnetoresistive element of the first example embodiment of the disclosure.

FIG. 11 is a side view showing the magnetic field generator of the first example embodiment of the disclosure.

FIG. 12 is a cross-sectional view showing a part of the magnetic sensor of the first example embodiment of the disclosure.

FIG. 13 is a cross-sectional view showing a part of the magnetic sensor of the first example embodiment of the disclosure.

FIG. 14 is an explanatory diagram for describing a shape of the magnetic field generator of the first example embodiment of the disclosure.

FIG. 15 is an explanatory diagram for describing a positional relationship between the magnetic field generator and the magnetoresistive element of the first example embodiment of the disclosure.

FIG. 16 is a cross-sectional view showing one process in a manufacturing method of the magnetic sensor according to the first example embodiment of the disclosure.

FIG. 17 is a cross-sectional view showing a process following the process shown in FIG. 16.

FIG. 18 is an explanatory diagram for describing a shape of a magnetic field generator of a first modification example of the magnetic sensor according to the first example embodiment of the disclosure.

FIG. 19 is a plan view showing magnetoresistive elements, magnetic field generators, lower electrodes, and upper electrodes of a second modification example of the magnetic sensor according to the first example embodiment of the disclosure.

FIG. 20 is a side view showing a magnetic field generator of a third modification example of the magnetic sensor according to the first example embodiment of the disclosure.

FIG. 21 is a side view showing a magnetic field generator of a fourth modification example of the magnetic sensor according to the first example embodiment of the disclosure.

FIG. 22 is a side view showing a magnetic field generator of a fifth modification example of the magnetic sensor according to the first example embodiment of the disclosure.

FIG. 23 is a side view showing a magnetic field generator of a sixth modification example of the magnetic sensor according to the first example embodiment of the disclosure.

FIG. 24 is a side view showing a magnetic field generator of a seventh modification example of the magnetic sensor according to the first example embodiment of the disclosure.

FIG. 25 is a cross-sectional view showing a part of a magnetic sensor of a second example embodiment of the disclosure.

FIG. 26 is an explanatory diagram for describing shapes of and a positional relationship between magnetic field generators and magnetoresistive elements of a third example embodiment of the disclosure.

FIG. 27 is an explanatory diagram for describing shapes of and a positional relationship between magnetic field generators and magnetoresistive elements of a modification example of the magnetic sensor according to the third example embodiment of the disclosure.

### DETAILED DESCRIPTION

An object of the disclosure is to provide a magnetic sensor capable of increasing a strength of a bias magnetic field to be applied to a magnetoresistive element.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference signs to avoid redundant descriptions.

### First Example Embodiment

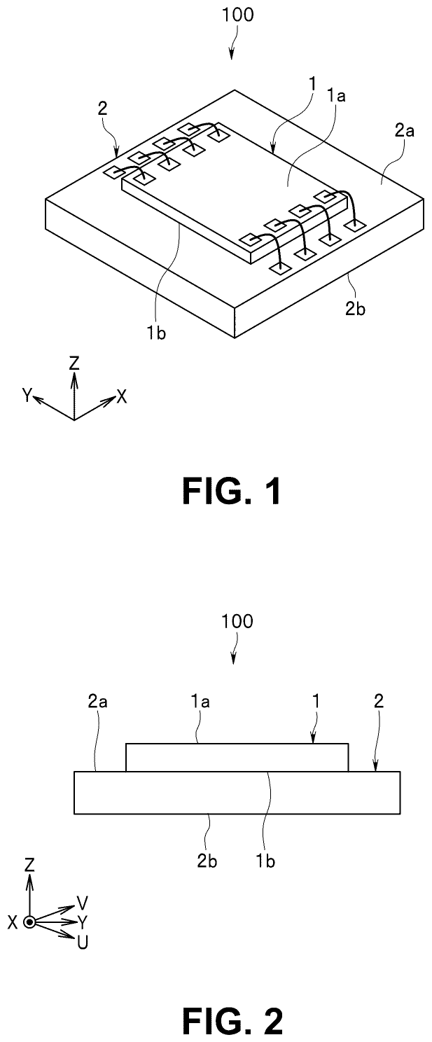

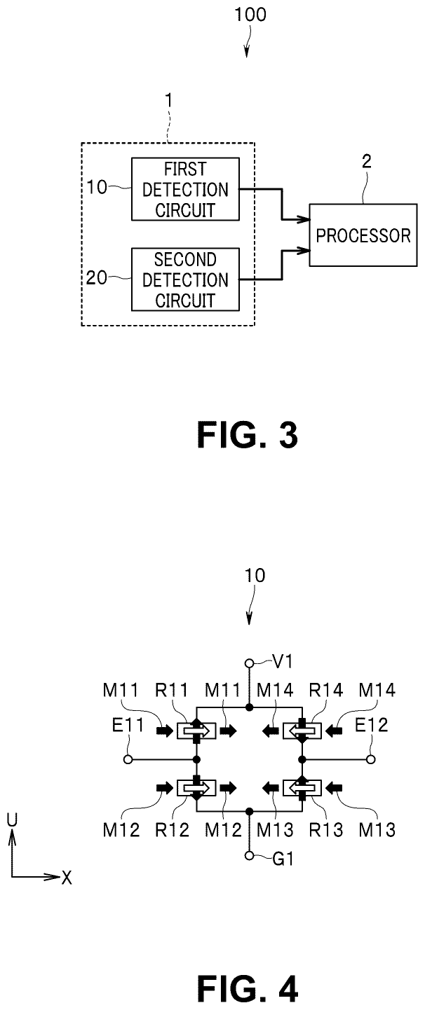

A configuration of a magnetic sensor device including a magnetic sensor according to a first example embodiment of the disclosure will initially be described with reference to FIG. 1 to FIG. 3. FIG. 1 is a perspective view showing a magnetic sensor device 100. FIG. 2 is a side view showing the magnetic sensor device 100. FIG. 3 is a functional block diagram showing the configuration of the magnetic sensor device 100.

The magnetic sensor device 100 of the example embodiment includes a magnetic sensor 1 according to the example embodiment and a processor 2. The magnetic sensor 1 is configured to detect a target magnetic field, which is a magnetic field to be detected by the magnetic sensor 1, and to generate at least one detection signal. The magnetic sensor 1 may be a geomagnetic field sensor that detects the geomagnetic field, a magnetic sensor for a position detection device that detects the position of a magnet moving in a specific direction, a magnetic sensor for angle sensors or magnetic encoders that detects a rotating magnetic field, or a magnetic sensor for current sensors that detects a magnetic field generated by a current to be detected.

The processor 2 is configured to generate at least one detection value having a correspondence with the target magnetic field, based on the at least one detection signal. The processor 2 is constituted, for example, by an application-specific integrated circuit (ASIC).

The magnetic sensor 1 and the processor 2 are each in a form of a chip having a rectangular parallelepiped shape. The magnetic sensor 1 includes a top surface 1a and a bottom surface 1b located on opposite sides of each other, and four side surfaces connecting the top surface 1a and the bottom surface 1b. The processor 2 includes a top surface 2a and a bottom surface 2b located on opposite sides of each other, and four side surfaces connecting the top surface 2a and the bottom surface 2b. The magnetic sensor 1 is mounted on the top surface 2a of the processor 2 in such an orientation that the bottom surface 1b of the magnetic sensor 1 faces the top surface 2a of the processor 2. The magnetic sensor 1 is bonded to the processor 2 by an adhesive, for example.

Now, X, Y, and Z directions are defined as shown in FIG. 1 and FIG. 2. The X direction, the Y direction, and the Z direction are orthogonal to one another. In the example embodiment, the Z direction is a direction perpendicular to the top surface 1a of the magnetic sensor 1 and from the bottom surface 1b to the top surface 1a of the magnetic sensor 1. The opposite directions to the X, Y, and Z directions will be expressed as −X, −Y, and −Z directions, respectively.

Hereinafter, the term “above” refers to positions located forward of a reference position in the Z direction, and “below” refers to positions opposite from the “above” positions with respect to the reference position. For each component of the magnetic sensor 1, the term “top surface” refers to a surface of the component lying at the end thereof in the Z direction, and “bottom surface” refers to a surface of the component lying at the end thereof in the −Z direction. The expression “when viewed in a specific direction (e.g., the Z direction)” means that an object is viewed from a position away in the specific direction or in one direction parallel to the specific direction.

As shown in FIG. 2, U and V directions are defined as follows. The U direction is a direction rotated from the Y direction to the −Z direction. The V direction is a direction rotated from the Y direction to the Z direction. In particular, in the example embodiment, the U direction is set to a direction rotated from the Y direction to the −Z direction by α, and the V direction is set to a direction rotated from the Y direction to the Z direction by α. Note that α is an angle greater than 0° and smaller than 90°. A −U direction refers to a direction opposite to the U direction, and a −V direction refers to a direction opposite to the V direction. The U direction and the V direction both are orthogonal to the X direction.

The magnetic sensor 1 includes a plurality of first pads (electrode pads) provided on the top surface 1a. The processor 2 includes a plurality of second pads (electrode pads) provided on the top surface 2a. In the magnetic sensor 1, of the plurality of first pads and the plurality of second pads, two corresponding pads are connected to each other by a bonding wire.

The magnetic sensor 1 includes a first detection circuit 10 and a second detection circuit 20. The first and second detection circuits 10 and 20 and the processor 2 are connected via the plurality of first pads, the plurality of second pads, and the plurality of bonding wires.

The first and second detection circuits 10 and 20 each include a plurality of magnetic detection elements, and are configured to detect the target magnetic field and generate at least one detection signal. In particular, in the example embodiment, the plurality of magnetic detection elements are a plurality of magnetoresistive elements. The magnetoresistive elements will hereinafter be referred to as MR elements.

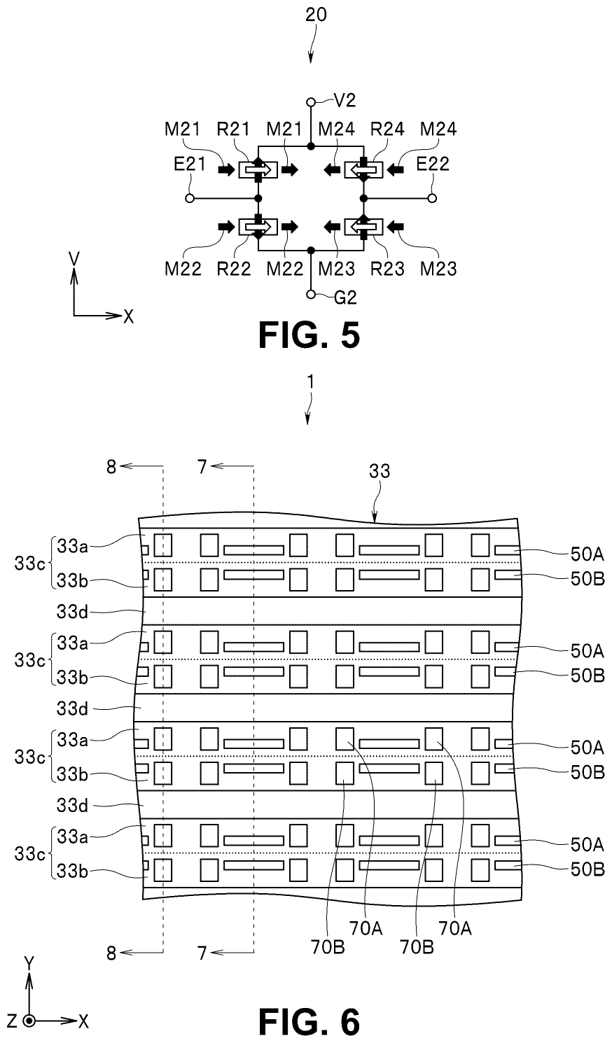

Next, circuit configurations of the first and second detection circuits 10 and 20 will be described with reference to FIG. 4 and FIG. 5. FIG. 4 is a circuit diagram showing the circuit configuration of the first detection circuit 10. FIG. 5 is a circuit diagram showing the circuit configuration of the second detection circuit 20.

The first detection circuit 10 is configured to detect a component of the target magnetic field in a direction parallel to the U direction, and generate at least one first detection signal having a correspondence with the component. The second detection circuit 20 is configured to detect a component of the target magnetic field in a direction parallel to the V direction, and generate at least one second detection signal having a correspondence with the component.

As shown in FIG. 4, the first detection circuit 10 includes four resistor sections R11, R12, R13, and R14, a power supply port V1, a ground port G1, a first output port E11, and a second output port E12. A plurality of MR elements of the first detection circuit 10 constitute the resistor sections R11, R12, R13, and R14.

The resistor section R11 is provided between the power supply port V1 and the first output port E11. The resistor section R12 is provided between the first output port E11 and the ground port G1. The resistor section R13 is provided between the second output port E12 and the ground port G1. The resistor section R14 is provided between the power supply port V1 and the second output port E12.

As shown in FIG. 5, the second detection circuit 20 includes four resistor sections R21, R22, R23, and R24, a power supply port V2, a ground port G2, a first output port E21, and a second output port E22. A plurality of MR elements of the second detection circuit 20 constitute the resistor sections R21, R22, R23, and R24.

The resistor section R21 is provided between the power supply port V2 and the first output port E21. The resistor section R22 is provided between the first output port E21 and the ground port G2. The resistor section R23 is provided between the second output port E22 and the ground port G2. The resistor section R24 is provided between the power supply port V2 and the second output port E22.

A voltage or current of a specific magnitude is applied to each of the power supply ports V1 and V2. Each of the ground ports G1 and G2 is connected to the ground.

Hereinafter, the plurality of MR elements of the first detection circuit 10 will be referred to as a plurality of first MR elements 50A. The plurality of MR elements of the second detection circuit 20 will be referred to as a plurality of second MR elements 50B. Since the first and second detection circuits 10 and 20 are components of the magnetic sensor 1, it can be said that the magnetic sensor 1 includes the plurality of first MR elements 50A and the plurality of second MR elements 50B. Any given MR element will be denoted by the reference sign 50.

In particular, in the example embodiment, the MR element 50 is a spin-valve MR element. The MR element 50 includes a magnetization pinned layer whose magnetization direction is fixed, a free layer whose magnetization direction is variable depending on the direction of the target magnetic field, and a gap layer disposed between the magnetization pinned layer and the free layer. The MR element 50 may be a tunneling magnetoresistive (TMR) element or a giant magnetoresistive (GMR) element. In the TMR element, the gap layer is a tunnel barrier layer. In the GMR element, the gap layer is a nonmagnetic conductive layer. The resistance of the MR element 50 changes with the angle that the magnetization direction of the free layer forms with respect to the magnetization direction of the magnetization pinned layer. The resistance of the MR element 50 is at its minimum value when the foregoing angle is 0°, and at its maximum value when the foregoing angle is 180°. In each MR element 50, the free layer has a shape anisotropy in which the direction of the magnetization easy axis is orthogonal to the magnetization direction of the magnetization pinned layer.

In FIG. 4 and FIG. 5, the plurality of solid arrows overlapping the respective resistor sections indicate the magnetization directions of the magnetization pinned layers of the MR elements 50. The plurality of hollow arrows overlapping the respective resistor sections indicate the magnetization directions of the free layers of the MR elements 50 when no target magnetic field is applied to the MR elements 50.

In the example shown in FIG. 4, the magnetization directions of the magnetization pinned layers in each of the resistor sections R11 and R13 are in the U direction. The magnetization directions of the magnetization pinned layers in each of the resistor sections R12 and R14 are in the −U direction. The free layer in each of the plurality of first MR elements 50A has a shape anisotropy in which the direction of the magnetization easy axis is parallel to the X direction. The magnetization directions of the free layers in each of the resistor sections R11 and R12 are in the X direction when no target magnetic field is applied to the first MR elements 50A. The magnetization directions of the free layers in each of the resistor sections R13 and R14 in the foregoing case are in the −X direction.

In the example shown in FIG. 5, the magnetization directions of the magnetization pinned layers in each of the resistor sections R21 and R23 are in the V direction. The magnetization directions of the magnetization pinned layers in each of the resistor sections R22 and R24 are in the −V direction. The free layer in each of the plurality of second MR elements 50B has a shape anisotropy in which the direction of the magnetization easy axis is parallel to the X direction. The magnetization directions of the free layers in each of the resistor sections R21 and R22 are in the X direction when no target magnetic field is applied to the second MR elements 50B. The magnetization directions of the free layers in each of the resistor sections R23 and R24 in the foregoing case are in the −X direction.

The magnetic sensor 1 further includes at least one magnetic field generator that generates a bias magnetic field to be applied to the at least one MR element 50. In particular, in the example embodiment, the magnetic sensor 1 includes a plurality of first magnetic field generators 70A and a plurality of second magnetic field generators 70B as the at least one magnetic field generator. Note that any given magnetic field generator will be denoted by the reference sign 70.

In FIG. 4, the arrows denoted by the reference signs M11, M12, M13, and M14 indicate the directions of the bias magnetic fields applied to the plurality of first MR elements 50A by the plurality of first magnetic field generators 70A. In the resistor sections R11 and R12, a bias magnetic field in the X direction is applied to the plurality of first MR elements 50A by the plurality of first magnetic field generators 70A. In the resistor sections R13 and R14, a bias magnetic field in the —X direction is applied to the plurality of first MR elements 50A by the plurality of first magnetic field generators 70A.

In FIG. 5, the arrows denoted by the reference signs M21, M22, M23, and M24 indicate the directions of the bias magnetic fields applied to the plurality of second MR elements 50B by the plurality of second magnetic field generators 70B. In the resistor sections R21 and R22, a bias magnetic field in the X direction is applied to the plurality of second MR elements 50B by the plurality of second magnetic field generators 70B. In the resistor sections R23 and R24, a bias magnetic field in the —X direction is applied to the plurality of second MR elements 50B by the plurality of second magnetic field generators 70B.

Note that, in view of factors such as the production accuracy of the MR elements 50 and the magnetic field generators 70, the magnetization directions of the magnetization pinned layers, the directions of the magnetization easy axes of the free layers, and the directions of the bias magnetic fields applied to the MR elements 50 by the plurality of magnetic field generators 70 may be slightly different from the foregoing directions. The magnetic pinned layers may be configured to be magnetized to include magnetization components in the foregoing directions as their main components. In such a case, the magnetization directions of the magnetization pinned layers are the same or substantially the same as the foregoing directions.

Next, the first and second detection signals will be described. The first detection signal will initially be described with reference to FIG. 4. As the strength of the component of the target magnetic field in the direction parallel to the U direction changes, the resistance of each of the resistor sections R11 to R14 of the first detection circuit 10 changes either so that the resistances of the resistor sections R11 and R13 increase and the resistances of the resistor sections R12 and R14 decrease, or so that the resistances of the resistor sections R11 and R13 decrease and the resistances of the resistor sections R12 and R14 increase. Thereby the electric potential at each of the first and second output ports E11 and E12 changes. The first detection circuit 10 is configured to generate a signal corresponding to the electric potential at the first output port E11 as a first detection signal S11, and generate a signal corresponding to the electric potential at the second output port E12 as a first detection signal S12.

Next, a second detection signal will be described with reference to FIG. 5. As the strength of the component of the target magnetic field in the direction parallel to the V direction changes, the resistance of each of the resistor sections R21 to R24 of the second detection circuit 20 changes either so that the resistances of the resistor sections R21 and R23 increase and the resistances of the resistor sections R22 and R24 decrease, or so that the resistances of the resistor sections R21 and R23 decrease and the resistances of the resistor sections R22 and R24 increase. Thereby the electric potential at each of the first and second output ports E21 and E22 changes. The second detection circuit 20 is configured to generate a signal corresponding to the electric potential at the first output port E21 as a second detection signal S21, and generate a signal corresponding to the electric potential at the second output port E22 as a second detection signal S22.

Next, the operation of the processor 2 will be described. The processor 2 is configured to generate a first detection value and a second detection value based on the first detection signals S11 and S12, and the second detection signals S21 and S22. The first detection value is a detection value corresponding to the component of the target magnetic field in a direction parallel to the Y direction. The second detection value is a detection value corresponding to the component of the target magnetic field in a direction parallel to the Z direction. Hereinafter, the first detection value is represented by the symbol Sy, and the second detection value is represented by the symbol Sz.

The processor 2 generates the first and second detection values Sy and Sz as follows, for example. First, the processor 2 generates a value S1 by an arithmetic including obtainment of a difference S11-S12 between the first detection signal S11 and the first detection signal S12, and generates a value S2 by an arithmetic including obtainment of a difference S21-S22 between the second detection signal S21 and the second detection signal S22. Next, the processor 2 calculates values S3 and S4 using the following expressions (1) and (2).

$$S 3 = ( S 2 + S 1 ) / ( 2 cos α ) \qquad ( 1 )$$

$$S 4 = ( S 2 - S 1 ) / ( 2 sin α ) \qquad ( 2 )$$

The first detection value Sy may be the value S3 itself, or may be a result of corrections, such as a gain adjustment and an offset adjustment, made to the value S3. In the same manner, the second detection value Sz may be the value S4 itself, or may be a result of corrections, such as a gain adjustment and an offset adjustment, made to the value S4.

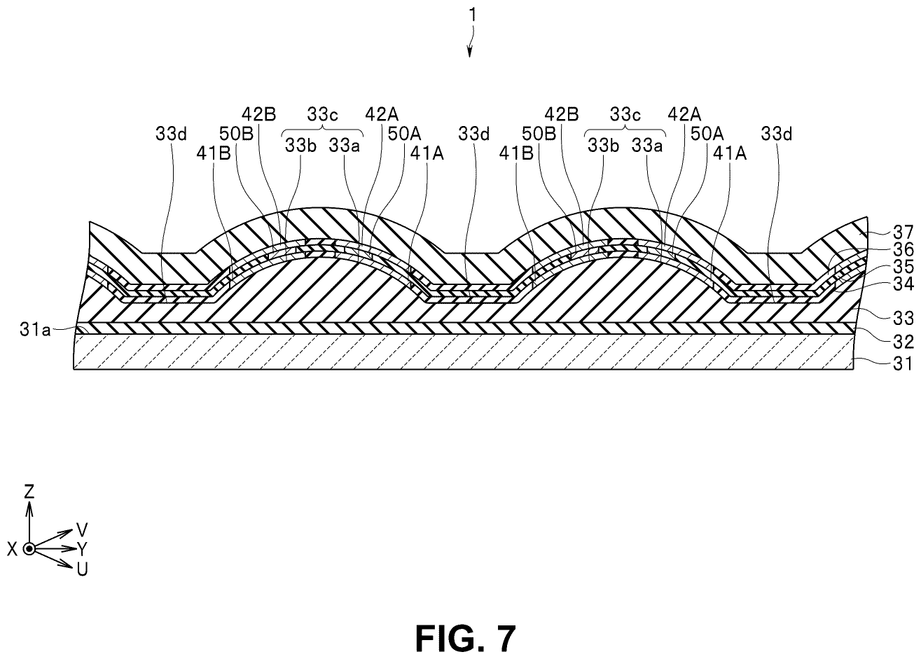

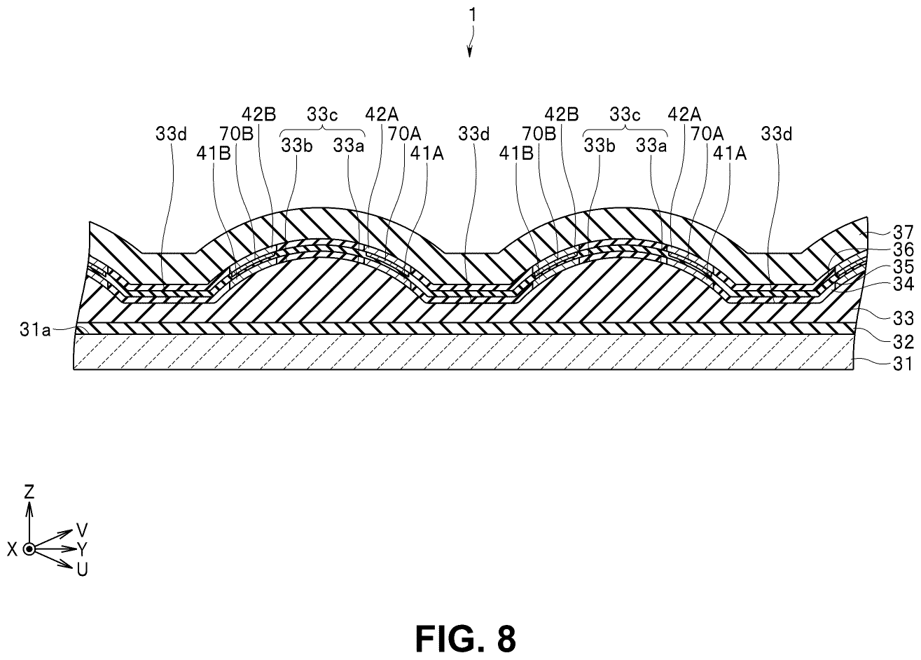

Next, the specific structure of the magnetic sensor 1 will be described in detail with reference to FIG. 6 to FIG. 8. FIG. 6 is a plan view showing a part of the magnetic sensor 1. FIG. 7 shows a part of a cross section at a position indicated by the line 7-7 in FIG. 6. FIG. 8 shows a part of a cross section at a position indicated by the line 8-8 in FIG. 6.

The magnetic sensor 1 includes a substrate 31 including a top surface 31a, insulating layers 32, 33, 34, 35, 36, and 37, a plurality of lower electrodes 41A, a plurality of lower electrodes 41B, a plurality of upper electrodes 42A, and a plurality of upper electrodes 42B. The top surface 31a of the substrate 31 is parallel to an XY plane. The Z direction is one direction perpendicular to the top surface 31a of the substrate 31. In the example embodiment, the top surface 31a of the substrate 31 may be used as a “reference plane”, which is reference for the dispositions and shapes of components of the magnetic sensor 1.

The insulating layers 32 and 33 are stacked in this order on the substrate 31. The plurality of lower electrodes 41A and the plurality of lower electrodes 41B are disposed on the insulating layer 33. The insulating layer 34 is disposed, on the insulating layer 33, around the plurality of lower electrodes 41A and around the plurality of lower electrodes 41B. The plurality of first MR elements 50A are disposed on the plurality of lower electrodes 41A. The plurality of second MR elements 50B are disposed on the plurality of lower electrodes 41B. The insulating layer 35 is disposed, on the plurality of lower electrodes 41A, the plurality of lower electrodes 41B, and the insulating layer 34, around the plurality of first MR elements 50A and around the plurality of second MR elements 50B. The plurality of upper electrodes 42A are disposed on the plurality of first MR elements 50A and the insulating layer 35. The plurality of upper electrodes 42B are disposed on the plurality of second MR elements 50B and the insulating layer 35. The insulating layer 36 is disposed, on the insulating layer 35, around the plurality of upper electrodes 42A and around the plurality of upper electrodes 42B. The insulating layer 37 is disposed on the plurality of upper electrodes 42A, the plurality of upper electrodes 42B, and the insulating layer 36.

The plurality of first magnetic field generators 70A and the plurality of second magnetic field generators 70B are embedded in the insulating layer 35. Each of the plurality of first magnetic field generators 70A is disposed at distances from the first MR elements 50A and the lower electrodes 41A. Each of the plurality of second magnetic field generators 70B is disposed at distances from the second MR elements 50B and the lower electrodes 41B. The magnetic sensor 1 may further include insulating films interposed between each of the plurality of first magnetic field generators 70A and each of the plurality of first MR elements 50A, between each of the plurality of second magnetic field generators 70B and each of the plurality of second MR elements 50B, between each of the plurality of first magnetic field generators 70A and each of the plurality of lower electrodes 41A, and between each of the plurality of second magnetic field generators 70B and each of the plurality of lower electrodes 41B.

The top surfaces of some of the plurality of first magnetic field generators 70A may be in contact with the bottom surfaces of the plurality of upper electrodes 42A. The top surfaces of some of the plurality of second magnetic field generators 70B may be in contact with the bottom surfaces of the plurality of upper electrodes 42B. Alternatively, the magnetic sensor 1 may further include other insulating films interposed between each of the plurality of first magnetic field generators 70A and the plurality of upper electrodes 42A, and between each of the plurality of second magnetic field generators 70B and the plurality of upper electrodes 42B.

The magnetic sensor 1 may include a support member that supports the plurality of first MR elements 50A and the plurality of second MR elements 50B. In particular, in the example embodiment, the support member includes the insulating layer 33. The insulating layer 33 is substantially disposed on the top surface 31a of the substrate 31. Note that FIG. 6 shows, among the components of the magnetic sensor 1, the insulating layer 33, the plurality of first MR elements 50A, the plurality of second MR elements 50B, the plurality of first magnetic field generators 70A, and the plurality of second magnetic field generators 70B.

The insulating layer 33 may include a plurality of facing surfaces 33c each protruding in a direction (Z direction) away from the top surface 31a of the substrate 31. Each of the plurality of facing surfaces 33c extends in the direction parallel to the X direction. The overall shape of the facing surface 33c is a semi-cylindrical curved surface obtained by moving the curved shape (arch shape) of the facing surface 33c shown in FIG. 7 and FIG. 8 along the direction parallel to the X direction. The plurality of facing surfaces 33c are aligned at a specific distance in the direction parallel to the Y direction.

Each of the plurality of facing surfaces 33c has an upper end portion, which is an end portion located at a position farthest from the top surface 31a of the substrate 31 in the facing surface 33c. In the example embodiment, the upper end portion of each of the plurality of facing surfaces 33c is assumed to extend in the direction parallel to the X direction. Now, focus is placed on any given one of the plurality of facing surfaces 33c. The facing surface 33c includes a first inclined surface 33a and a second inclined surface 33b. The first inclined surface 33a is a surface of the facing surface 33c that is on the Y direction side of the facing surface 33c with respect to the upper end portion of the facing surface 33c. The second inclined surface 33b is a surface of the facing surface 33c that is on the —Y direction side of the facing surface 33c with respect to the upper end portion of the facing surface 33c. In FIG. 6, the boundary between the first inclined surface 33a and the second inclined surface 33b is indicated by a dotted line.

The upper end portion of the facing surface 33c may be the boundary between the first inclined surface 33a and the second inclined surface 33b. In such a case, the dotted line shown in FIG. 6 indicates the upper end portion of the facing surface 33c.

The top surface 31a of the substrate 31 is parallel to the XY plane. The first inclined surface 33a and the second inclined surface 33b are each inclined relative to the top surface 31a of the substrate 31, i.e., the XY plane. In a cross section perpendicular to the top surface 31a of the substrate 31, the distance between the first inclined surface 33a and the second inclined surface 33b becomes smaller in a direction away from the top surface 31a of the substrate 31.

In the example embodiment, since the plurality of facing surfaces 33c are present, there are a plurality of first inclined surfaces 33a and a plurality of second inclined surfaces 33b. The insulating layer 33 includes the plurality of first inclined surfaces 33a and the plurality of second inclined surfaces 33b.

The insulating layer 33 further includes a flat surface 33d present around the plurality of facing surfaces 33c. The flat surface 33d is a surface parallel to the top surface 31a of the substrate 31. Each of the plurality of facing surfaces 33c protrudes in the Z direction from the flat surface 33d. In the example embodiment, the plurality of facing surfaces 33c are disposed at a distance. Therefore, the flat surface 33d is present between two facing surfaces 33c adjacent in the Y direction.

The insulating layer 33 may include groove portions recessed in the —Z direction from the flat surface 33d. In such a case, the plurality of facing surfaces 33c may be present in the groove portions.

The plurality of lower electrodes 41A are disposed on the plurality of first inclined surfaces 33a. The plurality of lower electrodes 41B are disposed on the plurality of second inclined surfaces 33b. As described above, the first inclined surface 33a and the second inclined surface 33b are each inclined relative to the reference plane, i.e., the top surface 31a of the substrate 31. Therefore, the top surface of each of the plurality of lower electrodes 41A and the top surface of each of the plurality of lower electrode 41B are also inclined relative to the top surface 31a of the substrate 31. Thus, it can be said that the plurality of first MR elements 50A and the plurality of second MR elements 50B are disposed on the inclined surfaces inclined relative to the top surface 31a of the substrate 31. The insulating layer 33 is a member for supporting each of the plurality of first MR elements 50A and the plurality of second MR elements 50B so as to allow each of the MR elements to be inclined relative to the top surface 31a of the substrate 31.

The plurality of first magnetic field generators 70A are substantially disposed on the plurality of first inclined surfaces 33a. Each of the plurality of first magnetic field generators 70A includes a bottom surface having a shape along the first inclined surface 33a.

The plurality of second magnetic field generators 70B are substantially disposed on the plurality of second inclined surfaces 33b. Each of the plurality of second magnetic field generators 70B includes a bottom surface having a shape along the second inclined surface 33b.

The facing surface 33c of the insulating layer 33 faces the first MR elements 50A, the second MR elements 50B, the first magnetic field generators 70A, and the second magnetic field generators 70B. The first and second inclined surfaces 33a and 33b are also curved surface parts of the facing surface 33c, respectively.

Now, focus is placed on any given one of the plurality of first magnetic field generators 70A and any given one of the plurality of second magnetic field generators 70B. As shown in FIG. 6, the plurality of first magnetic field generators 70A are disposed so that several first magnetic field generators 70A are arranged in each row in the X direction and each row in Y directions. Each of the plurality of first MR elements 50A is disposed between two first magnetic field generators 70A adjacent in the direction parallel to the X direction. Several first MR elements 50A and several first magnetic field generators 70A are arranged in a row along the direction parallel to the X direction on one first inclined surface 33a.

In the same manner, the plurality of second magnetic field generators 70B are disposed so that several second MR elements 50B are arranged in each row in the X direction and each row in the Y directions. Each of the plurality of second MR elements 50B is disposed between two second magnetic field generators 70B adjacent in the direction parallel to the X direction. Several second MR elements 50B and several second magnetic field generators 70B are arranged in a row in the direction parallel to the X direction on one second inclined surface 33b.

The rows of the several first MR elements 50A and the several first magnetic field generators 70A and the rows of the several second MR elements 50B and the several second magnetic field generators 70B are alternately arranged in the direction parallel to the Y direction. The plurality of first MR elements 50A and the plurality of second MR elements 50B may be disposed such that the first MR elements 50A and the second MR element 50B are alternately arranged in the direction parallel to the Y direction. The plurality of first magnetic field generators 70A and the plurality of second magnetic field generators 70B may be disposed such that the first magnetic field generators 70A and the second magnetic field generators 70B are alternately arranged in the direction parallel to the Y direction.

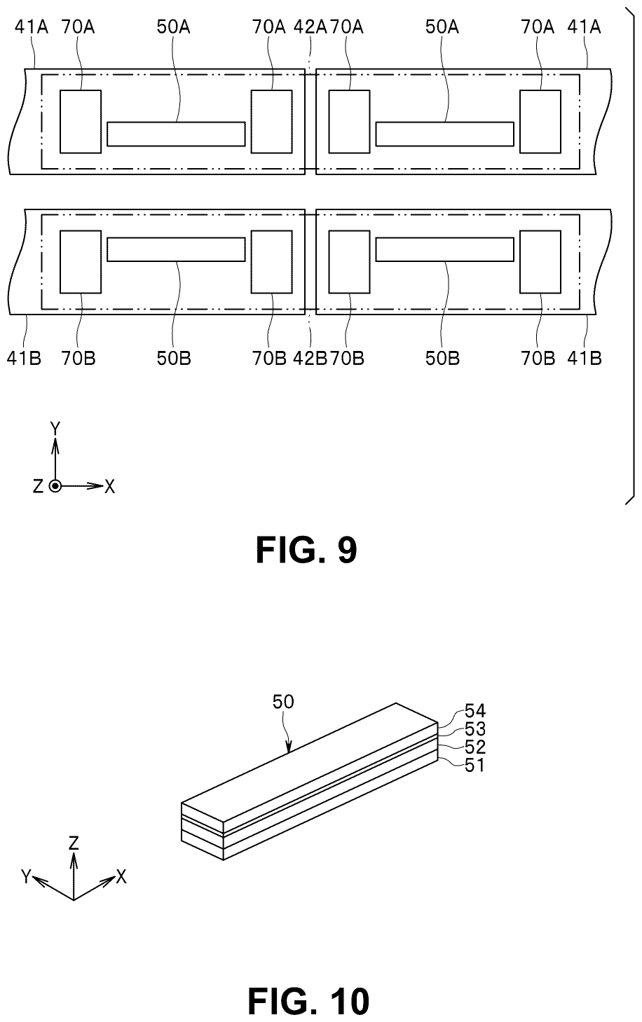

The plurality of first MR elements 50A are connected in series by the plurality of lower electrodes 41A and the plurality of upper electrodes 42A. The plurality of second MR elements 50B are connected in series by the plurality of lower electrodes 41B and the plurality of upper electrode 42B. A method for connecting the plurality of first MR elements 50A and a method for connecting the plurality of second MR elements 50B will now be described in detail with reference to FIG. 9.

As shown in FIG. 9, each lower electrode 41A has a long slender shape. Two lower electrodes 41A adjacent in the longitudinal direction of the lower electrodes 41A have a gap formed therebetween. The first MR elements 50A are disposed near both ends in the longitudinal direction on the top surface of the each lower electrode 41A. Each upper electrode 42A has a long slender shape, and electrically connects two adjacent first MR elements 50A that are disposed on the two lower electrodes 41A adjacent in the longitudinal direction of the lower electrodes 41A.

The first magnetic field generators 70A are disposed between the two first MR elements 50A adjacent in the longitudinal direction of the lower electrodes 41A. FIG. 9 shows an example where two first magnetic field generators 70A are disposed between the two first MR elements 50A. However, one first magnetic field generator 70A may be disposed between the two first MR elements 50A. FIG. 9 also shows an example where the two first magnetic field generators 70A between the two first MR elements 50A overlap the two lower electrodes 41A when viewed in the Z direction. However, two first magnetic field generators 70A between the two first MR elements 50A may overlap only one of the two lower electrodes 41A when viewed in the Z direction. Alternatively, the first magnetic field generator 70A may not overlap the two lower electrodes 41A when viewed in the Z direction. In addition, the first magnetic field generators 70A may or may not be in contact with the upper electrode 42A.

Although not shown in the drawings, one first MR element 50A located at the end of a row of several first MR elements 50A is connected to another first MR element 50A located at the end of another row of several first MR elements 50A adjacent in a direction intersecting the longitudinal direction of the lower electrodes 41A. The two first MR elements 50A are connected to each other by a not-shown electrode. The not-shown electrode may be an electrode connecting the bottom surfaces or the top surfaces of the two first MR elements 50A.

The above description of the first MR elements 50A, the first magnetic field generators 70A, the lower electrodes 41A, and the upper electrodes 42A also applies to the second MR elements 50B, the second magnetic field generators 70B, the lower electrodes 41B, and the upper electrodes 42B. If the first MR elements 50A, the first magnetic field generators 70A, the lower electrodes 41A, and the upper electrodes 42A in the above description are replaced with the second MR elements 50B, the second magnetic field generators 70B, the lower electrodes 41B, and the upper electrodes 42B, respectively, the description of the second MR elements 50B, the second magnetic field generators 70B, the lower electrodes 41B, and the upper electrodes 42B is obtained.

Next, a configuration of the MR element 50 will be described in more detail with reference to FIG. 10. In FIG. 10, the reference sign 52 denotes the magnetization pinned layer, the reference sign 53 the gap layer, and the reference sign 54 the free layer. The MR element 50 further includes an antiferromagnetic layer 51. The antiferromagnetic layer 51, the magnetization pinned layer 52, the gap layer 53, and the free layer 54 are stacked in this order from the lower electrode 41 to the upper electrode 42. The antiferromagnetic layer 51 is formed of an antiferromagnetic material, and is in exchange coupling with the magnetization pinned layer 52 to thereby fix the magnetization direction of the magnetization pinned layer 52. Note that the magnetization pinned layer 52 may be a so-called self-pinned layer (Synthetic Ferri Pinned layer, SFP layer). The self-pinned layer has a stacked ferri-structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

Note that the layers 51 to 54 of each MR element 50 may be stacked in the reverse order to that shown in FIG. 10.

In the first MR element 50A, the antiferromagnetic layer 51, the magnetization pinned layer 52, the gap layer 53, and the free layer 54 are stacked along a direction perpendicular to the first inclined surface 33a (see FIG. 6 and FIG. 7). In the second MR element 50B, the antiferromagnetic layer 51, the magnetization pinned layer 52, the gap layer 53, and the free layer 54 are stacked along a direction perpendicular to the second inclined surface 33b.

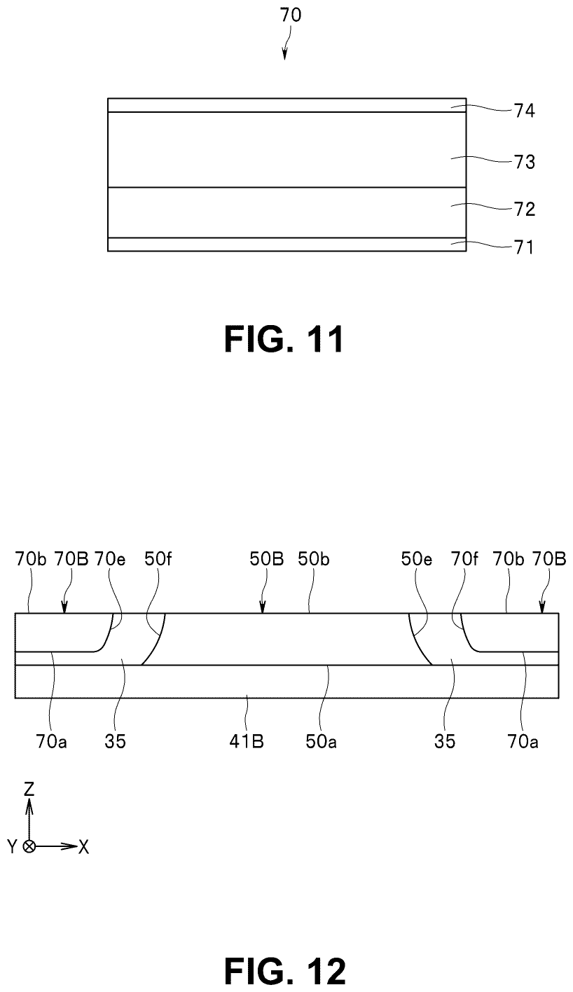

Next, a configuration of the magnetic field generator 70 will be described with reference to FIG. 11. FIG. 11 is a side view showing the magnetic field generator 70. The magnetic field generator 70 includes a ferromagnetic portion 73 and an antiferromagnetic portion 72 that is in contact with the ferromagnetic portion 73 and is in exchange coupling with the ferromagnetic portion 73.

The ferromagnetic portion 73 has its overall magnetization. The overall magnetization of the ferromagnetic portion 73 refers to the volume average of the vector sum of magnetic moments in units of atoms, crystal lattices, or the like in the entire ferromagnetic portion 73. Hereinafter, the overall magnetization of the ferromagnetic portion 73 will simply be referred to as the magnetization of the ferromagnetic portion 73.

In the magnetic field generator 70, the magnetization direction of the ferromagnetic portion 73 is defined by exchange coupling between the antiferromagnetic portion 72 and the ferromagnetic portion 73. The ferromagnetic portion 73 and the antiferromagnetic portion 72 generate a bias magnetic field to be applied to the MR element 50, based on the magnetization of the ferromagnetic portion 73. The magnetic field generator 70 thus constituted is highly resistant to disturbance magnetic fields.

The ferromagnetic portion 73 is formed of a ferromagnetic material containing one or more elements selected from the group consisting of Co, Fe, and Ni. Examples of such a ferromagnetic material include CoFe, CoFeB, and CoNiFe. The antiferromagnetic portion 72 is formed of an antiferromagnetic material such as IrMn or PtMn.

The magnetic field generator 70 further includes a buffer layer 71 and a cap layer 74. The buffer layer 71, the antiferromagnetic portion 72, the ferromagnetic portion 73, and the cap layer 74 are stacked in this order. Each of the buffer layer 71 and the cap layer 74 is formed of a nonmagnetic metallic material such as, for example, Ru, Ta, Cu, or Cr.

Now, with reference to FIG. 8 and FIG. 11, the stacking direction and bottom surfaces of the antiferromagnetic portion 72 and the ferromagnetic portion 73 of the first and second magnetic field generators 70A and 70B will be described. In the first magnetic field generator 70A, the antiferromagnetic portion 72 and the ferromagnetic portion 73 are stacked along a direction perpendicular to the first inclined surface 33a. The antiferromagnetic portion 72 and the ferromagnetic portion 73 each include a bottom surface facing the first inclined surface 33a and inclined relative to the reference plane, i.e., the top surface 31a of the substrate 31. Such a bottom surface can be implemented by forming each of the buffer layer 71 and the antiferromagnetic portion 72 in such a thickness that the shape of the first inclined surface 33a appears.

In the second magnetic field generator 70B, the antiferromagnetic portion 72 and the ferromagnetic portion 73 are stacked along a direction perpendicular to the second inclined surface 33b. The antiferromagnetic portion 72 and the ferromagnetic portion 73 each include a bottom surface facing the second inclined surface 33b and inclined relative to the reference plane, i.e., the top surface 31a of the substrate 31. Such a bottom surface can be implemented by forming each of the buffer layer 71 and the antiferromagnetic portion 72 in such a thickness that the shape of the second inclined surface 33b appears.

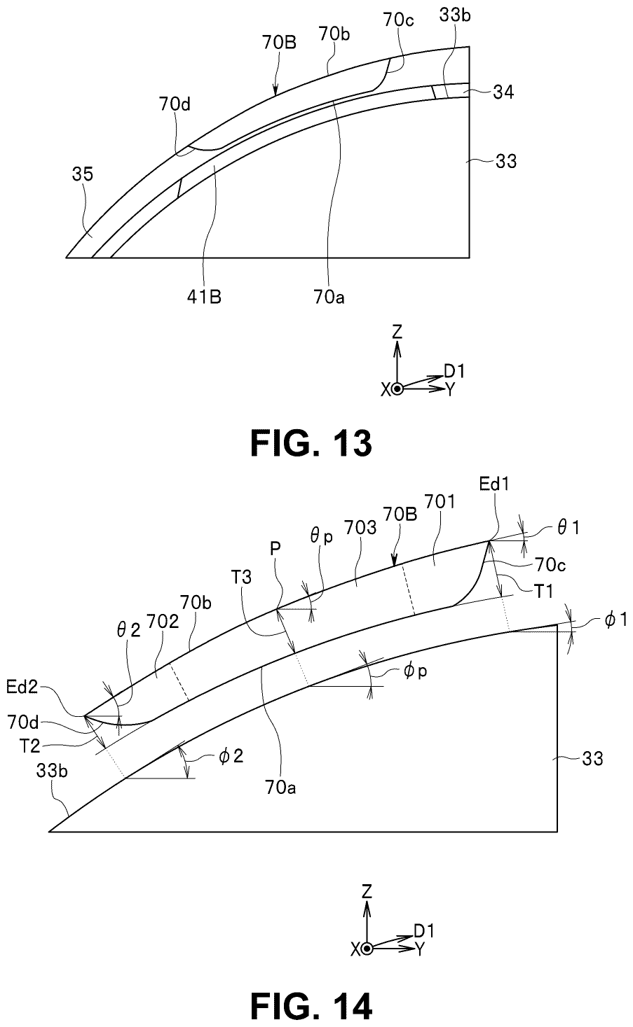

Next, features of the shapes and dispositions of the MR element 50 and the magnetic field generator 70 will be described with reference to FIG. 6 to FIG. 9, FIG. 12, and FIG. 13. FIG. 12 and FIG. 13 are each a cross-sectional view showing a part of the magnetic sensor 1. FIG. 12 shows a cross section that is parallel to the XZ plane and perpendicular to the top surface 31a of the substrate 31, and that intersects the second MR element 50B and the second magnetic field generator 70B. FIG. 13 shows a cross section that is parallel to the YZ plane and perpendicular to the top surface 31a of the substrate 31, and that intersects the second magnetic field generator 70B.

Hereinafter, even when descriptions are made with reference to FIG. 12 and FIG. 13, features common to the first MR element 50A and the second MR element 50B will be described as features of the MR element 50, and features common to the first magnetic field generator 70A and the second magnetic field generator 70B will be described as features of the magnetic field generator 70.

The magnetic field generator 70 is disposed at a distance from the MR element 50. The insulating layer 35 is interposed between the MR element 50 and the magnetic field generator 70.

The dimension of the magnetic field generator 70 in the direction parallel to the Y direction is greater than that of the MR element 50 in the direction parallel to the Y direction. When viewed in the X direction, at least a part of the MR element 50 overlaps the magnetic field generator 70. In particular, in the example embodiment, when viewed in the X direction, at least a part of the free layer 54 of the MR element 50 may overlap the ferromagnetic portion 73 of the magnetic field generator 70.

Now, a first direction D1 parallel to the YZ plane will be defined as shown in FIG. 13. The first direction D1 is a direction along the first inclined surface 33a or the second inclined surface 33b and away from the top surface 31a of the substrate 31. If the first direction D1 is defined as a direction along the second inclined surface 33b as shown in FIG. 13, the first direction D1 is a direction between the Y direction and the Z direction. Although not shown in the drawings, if the first direction D1 is defined as a direction along the first inclined surface 33a, the first direction D1 is a direction between the —Y direction and the Z direction.

In the following description, a direction along the first inclined surface 33a or the second inclined surface 33b and parallel to the first direction D1 is simply referred to as a direction along the inclined surface. This direction is also a direction along the inclined surface and a direction in which the distance from the top surface 31a of the substrate 31 changes. The dimension of the magnetic field generator 70 in the direction along the inclined surface is greater than the dimension of the MR element 50 in the direction along the inclined surface.

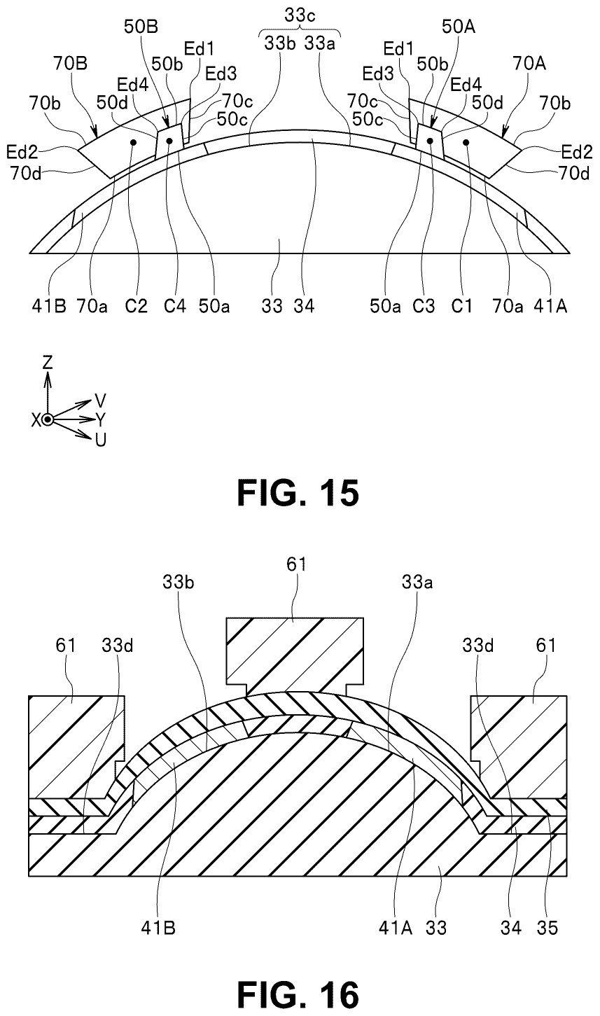

The MR element 50 includes a bottom surface 50a facing the first inclined surface 33a or the second inclined surface 33b, a top surface 50b opposite the bottom surface 50a, and four side surfaces 50c, 50d, 50e, and 50f that connect the bottom surface 50a and the top surface 50b. Note that the side surfaces 50c and 50d are shown in FIG. 15 described later. In particular, in the example embodiment, the side surfaces 50c to 50f are all located above the first inclined surface 33a or the second inclined surface 33b.

The side surface 50c is located at the end of the MR element 50 in the first direction D1. The side surface 50d is located at the end of the MR element 50 in a direction opposite to the first direction D1. In the first MR element 50A, the side surface 50c is located at the end of the first MR element 50A in the —Y direction, and the side surface 50d is located at the end of the first MR element 50A in the Y direction. In the second MR element 50B, the side surface 50c is located at the end of the second MR element 50B in the Y direction, and the side surface 50d is located at the end of the second MR element 50B in the —Y direction.

The side surface 50e is located at the end of the MR element 50 in the X direction. The side surface 50f is located at the end of the MR element 50 in the —X direction.

As shown in FIG. 12, each of the side surfaces 50e and 50f of the MR element 50 is inclined relative to the top surface 31a of the substrate 31. In one MR element 50, the distance between the side surface 50e and the side surface 50f in the direction parallel to the X direction decreases with increasing distance from the top surface 31a of the substrate 31. Although not shown in the drawings, each of the side surfaces 50c and 50d of the MR element 50 is inclined relative to the top surface 31a of the substrate 31. In one MR element 50, the distance between the side surface 50c and the side surface 50d in the direction along the inclined surface may decrease with increasing distance from the first inclined surface 33a or the second inclined surface 33b located below the MR element 50.

The magnetic field generator 70 includes a bottom surface 70a facing the first inclined surface 33a or the second inclined surface 33b, a top surface 70b opposite the bottom surface 70a, and four side surfaces 70c, 70d, 70e, and 70f that connect the bottom surface 70a and the top surface 70b. In particular, in the example embodiment, the side surfaces 70c to 70f are all located above the first inclined surface 33a or the second inclined surface 33b.

The side surface 70c is located at the end of the magnetic field generator 70 in the first direction D1. The side surface 70d is located at the end of the magnetic field generator 70 in the direction opposite to the first direction D1. In the first magnetic field generator 70A, the side surface 70c is located at the end of the first magnetic field generator 70A in the −Y direction, and the side surface 70d is located at the end of the first magnetic field generator 70A in the Y direction. In the second magnetic field generator 70B, the side surface 70c is located at the end of the second magnetic field generator 70B in the Y direction, and the side surface 70d is located at the end of the second magnetic field generator 70B in the −Y direction.

The side surface 70e is located at the end of the magnetic field generator 70 in the X direction. The side surface 70f is located at the end of the magnetic field generator 70 in the −X direction.

As shown in FIG. 12, each of the side surfaces 70e and 70f of the magnetic field generator 70 is inclined relative to the top surface 31a of the substrate 31. In one magnetic field generator 70, the distance between the side surface 70e and the side surface 70f in the direction parallel to the X direction increases with increasing distance from the top surface 31a of the substrate 31. As shown in FIG. 13, each of the side surfaces 70c and 70d of the magnetic field generator 70 is inclined relative to the top surface 31a of the substrate 31. In one magnetic field generator 70, the distance between the side surface 70c and the side surface 70d in the direction along the inclined surface increases with increasing distance from the first inclined surface 33a or the second inclined surface 33b located below the magnetic field generator 70.

Next, the shape of the magnetic field generator 70 will be described in more detail with reference to FIG. 13 and FIG. 14. FIG. 14 is an explanatory diagram for describing the shape of the magnetic field generator 70. The magnetic field generator 70 includes a first end portion Ed1 and a second end portion Ed2 located both ends of the magnetic field generator 70 in the direction parallel to the Y direction. The first end portion Ed1 is present at a position where the top surface 70b and the side surface 70c of the magnetic field generator 70 intersect. The second end portion Ed2 is present at a position where the top surface 70b and the side surface 70d of the magnetic field generator 70 intersect. The top surface 70b connects the first end portion Ed1 and the second end portion Ed2.

At least one of the first end portion Ed1 or the second end portion Ed2 is located above the first inclined surface 33a or the second inclined surface 33b. In the example embodiment, the first end portion Ed1 is located above the first inclined surface 33a or the second inclined surface 33b. The second end portion Ed2 may be located above the first inclined surface 33a or the second inclined surface 33b, or may be located above the flat surface 33d. In the example embodiment, the second end portion Ed2 is located above the first inclined surface 33a or the second inclined surface 33b.

The first end portion Ed1 is located at a position farther from the reference plane, i.e., the top surface 31a of the substrate 31 than the second end portion Ed2. In other words, the distance from the top surface 31a of the substrate 31 to the first end portion Ed1 is greater than the distance from the top surface 31a of the substrate 31 to the second end portion Ed2.

Here, of the magnetic field generator 70, a part including the first end portion Ed1, a part of the bottom surface 70a, a part of the top surface 70b, and the side surface 70c refers to a first part 701, a part including the second end portion Ed2, another part of the bottom surface 70a, another part of the top surface 70b, and the side surface 70d refers to a second part 702, and a part located between the first part 701 and the second part 702 refers to a third part 703. In FIG. 14, the boundary between the first part 701 and the third part 703, and the boundary between the second part 702 and the third part 703 are indicated by a broken line.

The magnetic field generator 70 has a thickness T which is the dimension in a direction perpendicular to the top surface 70b. In FIG. 14, the thickness T in the first part 701 is represented by the symbol T1, the thickness T in the second part 702 is represented by the symbol T2, and the thickness T in the third part 703 is represented by the symbol T3. The thicknesses T1 and T2 may be maximum thicknesses T in the first part 701 and the second part 702, respectively, or may be average thicknesses of the first part 701 and the second part 702, respectively. The thickness T3 may be a maximum thickness T in the third part 703, may be an average thickness T in the third part 703, or may be the thickness T at any given position P on the top surface 70b belonging to the third part 703. The any given position P is a position closer to the reference plane, i.e., the top surface 31a of the substrate 31 than the first end portion Ed1, and a position farther from the reference plane, i.e., the top surface 31a of the substrate 31 than the second end portion Ed2. In the description below, the thicknesses T1 and T2 are the maximum thicknesses T in the first part 701 and the second part 702, respectively, and the thickness T3 is the thickness T at the any given position P.

In the YZ cross section intersecting the magnetic field generator 70, the thickness T1 is greater than the thickness T2. In addition, in the above-described YZ cross section, the thickness T3 may be smaller than the thickness T1, and may be greater than the thickness T2. Furthermore, the thickness T3 may decrease from the first part 701 toward the second part 702.

In the example embodiment, the top surface 70b is inclined relative to the top surface 31a of the substrate 31. Here, an angle that the top surface 70b forms with respect to the top surface 31a of the substrate 31 is represented by the symbol θ. The angle θ is 0° or more and 900 or less. In addition, the angle θ at the first end portion Ed1 is represented by the symbol θ1, the angle θ at the second end portion Ed2 is represented by the symbol θ2, and the angle θ at the any given position P on the top surface 70b other than the first end portion Ed1 and the second end portion Ed2 is represented by the symbol θp.

In the YZ cross section intersecting the magnetic field generator 70, the angle θ1 is smaller than the angle θ2. As long as the requirement that the angle θ1 is smaller than the angle θ2 is satisfied, the angle θ1 may be within a range of 0° to 40°, for example. As long as the requirement that the angle θ1 is smaller than the angle θ2 is satisfied, the angle θ2 may be within a range of 20° to 60°, for example.

In addition, in the above YZ cross section, the angle θp is greater than the angle θ1 and smaller than the angle θ2. The angle θp may also increase from the first end portion Ed1 toward the second end portion Ed2.

Furthermore, in the example embodiment, an angle that the facing surface 33c forms with respect to the top surface 31a of the substrate 31 at any given position on the facing surface 33c changes depending on the distance from the top surface 31a of the substrate 31 to the any given position. Here, the angle that the facing surface 33c forms with respect to the top surface 31a of the substrate 31 is referred to as an inclined angle and represented by the symbol φ. The inclined angle φ is 0° or more and 90° or less. In addition, the inclined angle φ at a position on the facing surface 33c closest to the first end portion Ed1 is represented by the symbol φ1, the inclined angle φ at a position on the facing surface 33c closest to the second end portion Ed2 is represented by the symbol φ2, and the inclined angle φ at a position on the facing surface 33c closest to the any given position P on the top surface 70b other than the first end portion Ed1 and the second end portion Ed2 is represented by the symbol pp.

In the YZ cross section intersecting the magnetic field generator 70, the inclined angle φ1 is smaller than the inclined angle φ2. As long as the requirement that the inclined angle φ1 is smaller than the inclined angle φ2 is satisfied, the inclined angle φ1 may be within a range of 0° to 40°, for example. As long as the requirement that the inclined angle φ1 is smaller than the inclined angle φ2 is satisfied, the inclined angle φ2 may be within a range of 20° to 60°, for example.

In addition, in the above-described YZ cross section, the inclined angle φp is greater than the inclined angle φ1 and smaller than the inclined angle φ2. The inclined angle φp may also increase from the first end portion Ed1 toward the second end portion Ed2.

Next, a positional relationship between the magnetic field generator 70 and the MR element 50 will be described with reference to FIG. 9 and FIG. 15. FIG. 15 is an explanatory diagram for describing the positional relationship between the magnetic field generator 70 and the MR element 50. In FIG. 15, the positional relationship between the magnetic field generator 70 and the MR element 50 when viewed in the X direction is schematically shown. Note that, for convenience, the size of the magnetic field generator 70 is emphasized compared to that of the MR element 50 in FIG. 15.

At least a part of the first MR element 50A is disposed to overlap the first magnetic field generator 70A when viewed in the X direction. At least a part of the second MR element 50B is disposed to overlap the second magnetic field generator 70B when viewed in the X direction.

The MR element 50 includes a third end portion Ed3 and a fourth end portion Ed4 located at both ends of the MR element 50 in the direction parallel to the Y direction. The third end portion Ed3 is present at a position where the top surface 50b and the side surface 50c of the MR element 50 intersect. The fourth end portion Ed4 is present at a position where the top surface 50b and the side surface 50d of the MR element 50 intersect. The top surface 50b connects the third end portion Ed3 and the fourth end portion Ed4. The third end portion Ed3 and the fourth end portion Ed4 are located above the first inclined surface 33a or the second inclined surface 33b.

The third end portion Ed3 is located at a position farther from the reference plane, i.e., the top surface 31a of the substrate 31 than the fourth end portion Ed4. In other words, the distance from the top surface 31a of the substrate 31 to the third end portion Ed3 is greater than the distance from the top surface 31a of the substrate 31 to the fourth end portion Ed4.

The MR element 50 is disposed so that the distance between the first end portion Ed1 of the magnetic field generator 70 and the third end portion Ed3 of the MR element 50 in the direction parallel to the Y direction is smaller than the distance between the second end portion Ed2 of the magnetic field generator 70 and the fourth end portion Ed4 of the MR element 50 in the direction parallel to the Y direction. In particular, in the example embodiment, the first MR element 50A is disposed so that the distance between the first end portion Ed1 of the first magnetic field generator 70A and the third end portion Ed3 of the first MR element 50A in the direction parallel to the Y direction is smaller than the distance between the second end portion Ed2 of the first magnetic field generator 70A and the fourth end portion Ed4 of the first MR element 50A in the direction parallel to the Y direction. In addition, the second MR element 50B is disposed so that the distance between the first end portion Ed1 of the second magnetic field generator 70B and the third end portion Ed3 of the second MR element 50B in the direction parallel to the Y direction is smaller than the distance between the second end portion Ed2 of the second magnetic field generator 70B and the fourth end portion Ed4 of the second MR element 50B in the direction parallel to the Y direction.

Here, focus is placed on the first MR element 50A, the second MR element 50B, the first magnetic field generator 70A, and the second magnetic field generator 70B disposed on one facing surface 33c. In FIG. 15, the reference sign C1 indicates the center of the first magnetic field generator 70A in the direction parallel to the Y direction, the reference sign C2 indicates the center of the second magnetic field generator 70B in the direction parallel to the Y direction, the reference sign C3 indicates the center of the first MR element 50A in the direction parallel to the Y direction, and the reference sign C4 indicates the center of the second MR element 50B in the direction parallel to the Y direction. Note that the centers C1 and C2 may also be the center of a plurality of layers constituting the magnetic field generator 70 in the stacking direction. Similarly, the centers C3 and C4 may also be the center of a plurality of layers constituting the MR element 50 in the stacking direction.

As shown in FIG. 15, the distance between the center C1 and the center C2 may be different from the distance between the center C3 and the center C4. In an example shown in FIG. 15, the distance between the center C1 and the center C2 is greater than the distance between the center C3 and the center C4.

Note that when focus is placed on the first MR element 50A, the second MR element 50B, the first magnetic field generator 70A, and the second magnetic field generator 70B disposed on two facing surfaces 33c, the above relationship of the distances is reversed. In other words, when focus is placed on the first MR element 50A and the first magnetic field generator 70A disposed on the facing surface 33c located on the —Y direction side and the second MR element 50B and the second magnetic field generator 70B disposed on the facing surface 33c located on the Y direction side, the distance between the center C1 and the center C2 is smaller than the distance between the center C3 and the center C4.

Next, a manufacturing method of the magnetic sensor 1 in the example embodiment will be briefly described. The process of manufacturing the magnetic sensor 1 includes a process of forming the insulating layer 33 as a support member, a process of forming the plurality of MR elements 50, and a process of forming the plurality of magnetic field generators 70. The plurality of MR elements 50 and the plurality of magnetic field generators 70 are formed on the insulating layer 33.

Initially, the process of forming the plurality of MR elements 50 will be described. In the process of forming the plurality of MR elements 50, first, a plurality of initial MR elements to later become the plurality of MR elements 50 are formed. Each of the plurality of initial MR elements includes an initial magnetization pinned layer to later become the magnetization pinned layer 52, the antiferromagnetic layer 51, the gap layer 53, and the free layer 54.

Next, the magnetization direction of the initial magnetization pinned layer is fixed using laser light and an external magnetic field including a component in a specific direction. For example, in the plurality of initial MR elements to later become the plurality of first MR elements 50A constituting the resistor sections R11 and R13 of the first detection circuit 10, the plurality of initial MR elements are irradiated with laser light while an external magnetic field in the Y direction is applied thereto. The irradiation of the laser light is performed so that the temperature of the plurality of initial MR elements irradiated with the laser light becomes equal to or higher than a blocking temperature of the antiferromagnetic layer 51. The temperature of the plurality of initial MR elements can be adjusted, for example, by the intensity and the pulse width of the laser light.

The external magnetic field in the Y direction can be divided into a component in the U direction and a component in a direction orthogonal to the U direction. After the irradiation of the laser light, when the temperature of the plurality of initial MR elements becomes lower than the blocking temperature, the magnetization directions of the initial magnetization pinned layers are fixed in the U direction. This causes the initial magnetization pinned layers to become the magnetization pinned layers 52, and the initial MR elements to become the first MR elements 50A.

In the plurality of initial MR elements to later become the plurality of first MR elements 50A constituting the resistor sections R12 and R14 of the first detection circuit 10, the magnetization direction of the initial magnetization pinned layer of each of the plurality of initial MR elements can be fixed in the −U direction by using an external magnetic field in the −Y direction. The plurality of first MR elements 50A are thus formed. The magnetization direction of the magnetization pinned layer 52 of each of the plurality of second MR elements 50B constituting each of the resistor sections R21 to R24 of the second detection circuit 20 is also fixed by the same method as with the magnetization pinned layer 52 of each of the plurality of first MR elements 50A.

The MR element 50 is completed by patterning a stacked film by etching so that the side surface of the MR element 50 is formed on the stacked film, after the magnetization direction of the magnetization pinned layer 52 is fixed. Note that the process of fixing the magnetization directions of the initial magnetization pinned layers may be performed after the side surface of the MR element 50 is formed on the stacked film. Next, the insulating layer 35 is formed around the plurality of first MR elements 50A and around the plurality of second MR elements 50B.

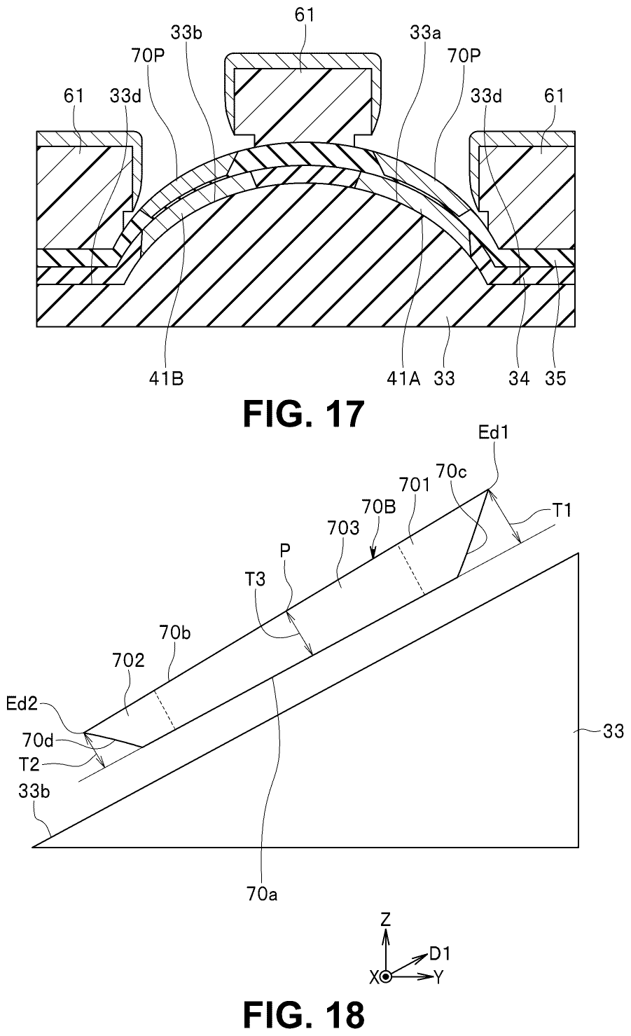

Next, the process of forming the plurality of magnetic field generators 70 will be described with reference to FIG. 16 and FIG. 17. FIG. 16 and FIG. 17 each show a stack in the manufacturing process of the magnetic sensor 1. The process of forming the plurality of magnetic field generators 70 may be performed after the plurality of MR elements 50 and the insulating layer 35 are formed.

In the process of forming the plurality of magnetic field generators 70, first, a plurality of photoresist masks 61 are formed on the MR element 50 and the insulating layer 35, as shown in FIG. 16. Next, using the plurality of photoresist mask 61 as etching masks, the insulating layer 35 is etched by ion milling, for example, so that a plurality of groove portions are formed in the insulating layer 35. The plurality of groove portions each have a shape corresponding to the plurality of magnetic field generators 70.

Next, as shown in FIG. 17, a plurality of initial magnetic field generators 70P are formed so that the plurality of initial magnetic field generators 70P to later become the magnetic field generators 70 are housed within the plurality of groove portions, leaving the plurality of photoresist masks 61 in place. Each of the plurality of initial magnetic field generators 70P at least includes an initial ferromagnetic portion to later become the ferromagnetic portion 73, and the antiferromagnetic portion 72. Next, the plurality of photoresist masks 61 are removed.

Next, the magnetization direction of the initial ferromagnetic portion is fixed using laser light and an external magnetic field including a component in a specific direction. The method of fixing the magnetization direction of the initial ferromagnetic portion is the same as the method of fixing the magnetization direction of the initial magnetization pinned layer. That is, each of the plurality of initial magnetic field generators 70P is irradiated with laser light while an external magnetic field is applied thereto. The irradiation of the laser light is performed so that the temperature of the plurality of initial magnetic field generators 70P irradiated with the laser light becomes equal to or higher than a blocking temperature of the antiferromagnetic portion 72. The temperature of the plurality of initial magnetic field generators 70P can be adjusted, for example, by the intensity and the pulse width of the laser light. After the irradiation of the laser light, when the temperature of the plurality of initial magnetic field generators 70P becomes lower than the blocking temperature, the magnetization direction of the initial ferromagnetic portion is fixed in the above-described specific direction. This causes the initial ferromagnetic portion to become the ferromagnetic portion 73, and the plurality of initial magnetic field generators 70P to become the plurality of magnetic field generators 70.

For example, in the plurality of initial magnetic field generators 70P to later become the plurality of first magnetic field generators 70A that apply a bias magnetic field to the plurality of first MR elements 50A constituting the resistor sections R11 and R12 of the first detection circuit 10, the magnetization direction of the initial ferromagnetic portion is fixed in the X direction by irradiating the plurality of initial magnetic field generators 70P with laser light while an external magnetic field in the X direction is applied thereto. This causes the initial ferromagnetic portion to become the ferromagnetic portion 73, and the initial magnetic field generator 70P to become the first magnetic field generator 70A. In the plurality of initial magnetic field generators 70P to later become the plurality of first magnetic field generators 70A that apply a bias magnetic field to the plurality of first MR elements 50A constituting the resistor sections R13 and R14 of the first detection circuit 10, the magnetization direction of the initial ferromagnetic portion of each of the plurality of initial magnetic field generators 70P can be fixed in the −X direction by using an external magnetic field in the −X direction. The plurality of first magnetic field generators 70A are thus formed. The plurality of second magnetic field generators 70B are also formed using a method similar to that used to form the plurality of first magnetic field generators 70A.

Note that the intensity of the laser light used to fix the magnetization direction of the initial ferromagnetic portion may be smaller than the intensity of the laser light used to fix the magnetization direction of the initial magnetization pinned layer. The intensity of the laser light used to fix the magnetization direction of the initial ferromagnetic portion may be an intensity such that the change in magnetoresistive change rate, which is the ratio of the magnetoresistive change to the resistance of the MR element 50, is suppressed.

Next, effects of the magnetic sensor 1 according to the example embodiment will be described. In the example embodiment, the plurality of initial magnetic field generators 70P are formed on the first inclined surface 33a and the second inclined surface 33b. The thickness of the initial magnetic field generator 70P (the dimension in a direction perpendicular to the first inclined surface 33a or the second inclined surface 33b) becomes smaller as the inclined angle φ increases. In other words, in the example embodiment, due to the first and second inclined surfaces 33a and 33b, the second part 702 is formed so that the thickness T2 of the second part 702 is smaller than the thickness T1 of the first part 701.

In addition, in the example embodiment, the plurality of initial magnetic field generators 70P are formed leaving the plurality of photoresist masks 61 in place, as described above. Generally, the thickness (the dimension in the direction parallel to the Z direction) of the photoresist mask 61 located on the flat surface 33d is greater than the thickness of the photoresist mask 61 located on the facing surface 33c. In such a case, due to a shadow of the photoresist mask 61 located on the flat surface 33d, the thickness of a part of the initial magnetic field generator 70P formed near the photoresist mask 61 located on the flat surface 33d is smaller than the thickness of a part of the initial magnetic field generator 70P formed near the photoresist mask 61 located on the facing surface 33c. In other words, in the example embodiment, due to the photoresist mask 61, the second part 702 is formed so that the thickness T2 of the second part 702 is smaller than the thickness T1 of the first part 701.

In contrast, in the example embodiment, the MR element 50 is disposed so that the distance between the first end portion Ed1 of the magnetic field generator 70 and the third end portion Ed3 of the MR element 50 in the direction parallel to the Y direction is smaller than the distance between the second end portion Ed2 of the magnetic field generator 70 and the fourth end portion Ed4 of the MR element 50 in the direction parallel to the Y direction. In the YZ cross section intersecting the magnetic field generator 70, the thickness T1 of the first part 701 of the magnetic field generator 70 is greater than the thickness T2 of the second part 702 of the magnetic field generator 70. In other words, in the example embodiment, the MR element 50 is disposed so as to be close to the first part 701, which has the great thickness T in the magnetic field generator 70. According to the example embodiment, this allows the strength of the bias magnetic field to be applied to the MR element 50 to be increased compared to when the MR element 50 is disposed so as to be close to the second part 702, which has the small thickness T, in the magnetic field generator 70, or when the MR element 50 is disposed so that the center part of the MR element 50 in the direction parallel to the Y direction and the center part of the magnetic field generator 70 in the direction parallel to the Y direction overlap.

### Modification Examples

Next, first to seventh modification examples of the magnetic sensor 1 according to the example embodiment will be described. Initially, the first modification example will be described with reference to FIG. 18. FIG. 18 is an explanatory diagram for describing a shape of a magnetic field generator 70 of a first modification example of the magnetic sensor 1. In the first modification example, each of the plurality of first inclined surfaces 33a and the plurality of second inclined surfaces 33b included in the plurality of facing surfaces 33c is formed into a plane or substantially plane shape. Although not shown in the drawings, the shape of the facing surface 33c in the cross section parallel to the YZ plane is a triangular shape. The overall shape of each of the plurality of facing surfaces 33c is a triangular roof shape formed by moving the triangular shape along the direction parallel to the X direction.

In the first modification example, each of the bottom surface 70a and the top surface 70b of the magnetic field generator 70 is formed into a plane or a substantially plane shape. In the first modification example, the requirements for the thicknesses T1, T2, and T3 described with reference to FIG. 14 are also satisfied.

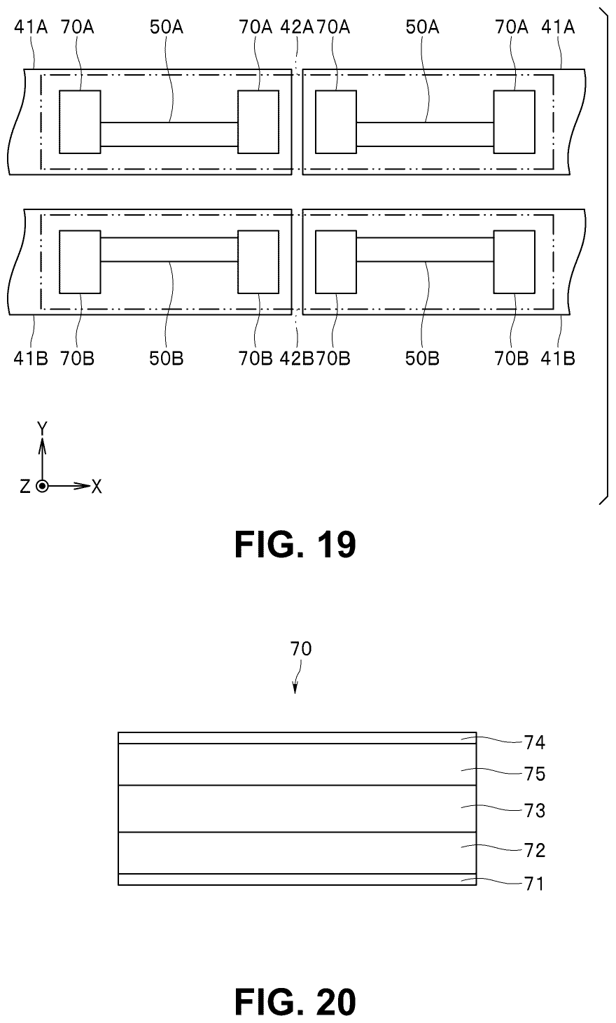

Next, the second modification example will be described with reference to FIG. 19. FIG. 19 is a plan view showing the MR elements 50, the magnetic field generators 70, the lower electrodes 41, and the upper electrodes 42 of the second modification example. In the second modification example, instead of the insulating layer 35, an insulating film formed along the side surface of the MR element 50 is interposed between the MR element 50 and the magnetic field generator 70. When viewed in the Z direction, a part of the magnetic field generator 70 overlaps a part of the MR element 50.

Next, the third modification example will be described with reference to FIG. 20. FIG. 20 is a side view showing the magnetic field generator 70 of the third modification example. In the third modification example, the magnetic field generator 70 further includes an antiferromagnetic portion 75. The antiferromagnetic portion 75 is disposed between the ferromagnetic portion 73 and the cap layer 74. The antiferromagnetic portion 75 is formed of an antiferromagnetic material such as IrMn or PtMn. In the magnetic field generator 70 of the third modification example, the magnetization direction of the ferromagnetic portion 73 is defined by the antiferromagnetic portion 72 and the antiferromagnetic portion 75 being exchange-coupled with the ferromagnetic portion 73.

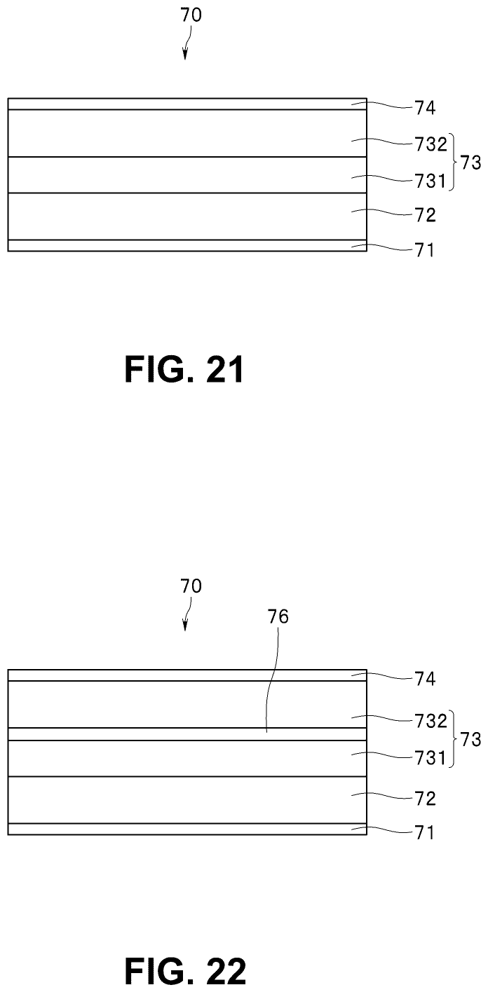

Next, the fourth modification example will be described with reference to FIG. 21. FIG. 21 is a side view showing the magnetic field generator 70 of the fourth modification example. In the fourth modification example, the ferromagnetic portion 73 of the magnetic field generator 70 includes a ferromagnetic layer 731 and a ferromagnetic layer 732. The buffer layer 71, the antiferromagnetic portion 72, the ferromagnetic layer 731, the ferromagnetic layer 732, and the cap layer 74 are stacked in this order. The ferromagnetic layers 731 and 732 are each formed of a ferromagnetic material containing one or more elements selected from the group consisting of Co, Fe, and Ni. In the fourth modification example, the ferromagnetic layer 731 and the ferromagnetic layer 732 each have magnetization in the same direction.

In the fourth modification example, the ferromagnetic layer 731 may be formed of a ferromagnetic material capable of increasing the exchange coupling energy between the ferromagnetic layer 731 and the antiferromagnetic portion 72, and the ferromagnetic layer 732 may be formed of a ferromagnetic material having a saturation magnetic flux density greater than that of the ferromagnetic material constituting the ferromagnetic layer 731. In such a case, the strength of the bias magnetic field generated by the magnetic field generator 70 can be increased while the exchange coupling energy between the ferromagnetic portion 73 including the ferromagnetic layers 731 and 732 and the antiferromagnetic portion 72 is increased, and the magnetic field generator 70 can be made smaller in size. An example of the ferromagnetic layer 731 includes a Co₇₀Fe₃₀ layer. An example of the ferromagnetic layer 732 includes a Co₃₀Fe₇₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fe.

Next, the fifth modification example will be described with reference to FIG. 22. FIG. 22 is a side view showing the magnetic field generator 70 of the fifth modification example. In the fifth modification example, the ferromagnetic portion 73 of the magnetic field generator 70 includes the ferromagnetic layer 731 and the ferromagnetic layer 732. The magnetic field generator 70 further includes a nonmagnetic layer 76. The buffer layer 71, the antiferromagnetic portion 72, the ferromagnetic layer 731, the nonmagnetic layer 76, the ferromagnetic layer 732, and the cap layer 74 are stacked in this order. The ferromagnetic layers 731 and 732 are each formed of a ferromagnetic material containing one or more elements selected from the group consisting of Co, Fe, and Ni. The ferromagnetic layer 731 and the ferromagnetic layer 732 may be formed of the same ferromagnetic material or different ferromagnetic materials. The nonmagnetic layer 76 is formed of a nonmagnetic metallic material such as, for example, Ru.

In the fifth modification example, the ferromagnetic layer 731 and the ferromagnetic layer 732 may be ferromagnetically exchange-coupled with each other via the nonmagnetic layer 76 so that the magnetization directions thereof are the same. In such a case, the ferromagnetic layer 731 and the ferromagnetic layer 732 have magnetization in the same direction. The thickness of the nonmagnetic layer 76 is set to a thickness so as not to lose the exchange coupling between the ferromagnetic layer 731 and the ferromagnetic layer 732. By providing the nonmagnetic layer 76, it is possible to adjust the coercivity of the ferromagnetic portion 73 and to adjust the surface roughness of the base of the ferromagnetic layer 732.

Alternatively, the ferromagnetic layer 731 and the ferromagnetic layer 732 may be antiferromagnetically exchange-coupled with each other via the nonmagnetic layer 76 by the RKKY interaction. In such a case, the magnetization direction of the ferromagnetic layer 731 and the magnetization direction of the ferromagnetic layer 732 are opposite to each other. The magnetization direction of the ferromagnetic portion 73 is the same as the magnetization direction of the ferromagnetic layer 731. When the ferromagnetic layer 731 and the ferromagnetic layer 732 are antiferromagnetically exchange-coupled with each other, the net moment of the ferromagnetic portion 73 becomes small. Therefore, in the ferromagnetic portion 73, the Zeeman energy, which is the energy produced by the external magnetic field being acting on the magnetic moment, becomes small. As a result, even when an external magnetic field is applied, the magnetization direction of the ferromagnetic portion 73 is less likely to incline than when the Zeeman energy is large.

The thickness of the nonmagnetic layer 76 is set so that the respective magnetization directions of the ferromagnetic layer 731 and the ferromagnetic layer 732 due to the RKKY interaction become expected directions, and the strength of the exchange coupling by the RKKY interaction becomes an expected strength.

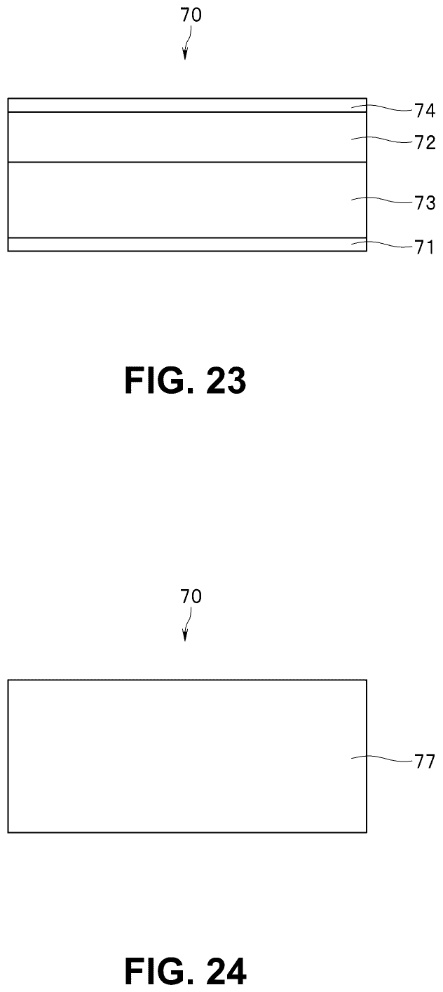

Next, the sixth modification example will be described with reference to FIG. 23. FIG. 23 is a side view showing the magnetic field generator 70 of the sixth modification example. In the sixth modification, the buffer layer 71, the antiferromagnetic portion 72, the ferromagnetic portion 73, and the cap layer 74 of the magnetic field generator 70 are stacked in the order of the buffer layer 71, the ferromagnetic portion 73, the antiferromagnetic portion 72, and the cap layer 74.

Next, the seventh modification example will be described with reference to FIG. 24. FIG. 24 is a side view showing the magnetic field generator 70 of the seventh modification example. In the seventh modification example, the magnetic field generator 70 includes a magnet 77 formed of a hard magnetic material, instead of the antiferromagnetic portion 72 and the ferromagnetic portion 73. The magnetic field generator 70 may or may not include the buffer layer 71 and the cap layer 74.

### Second Example Embodiment

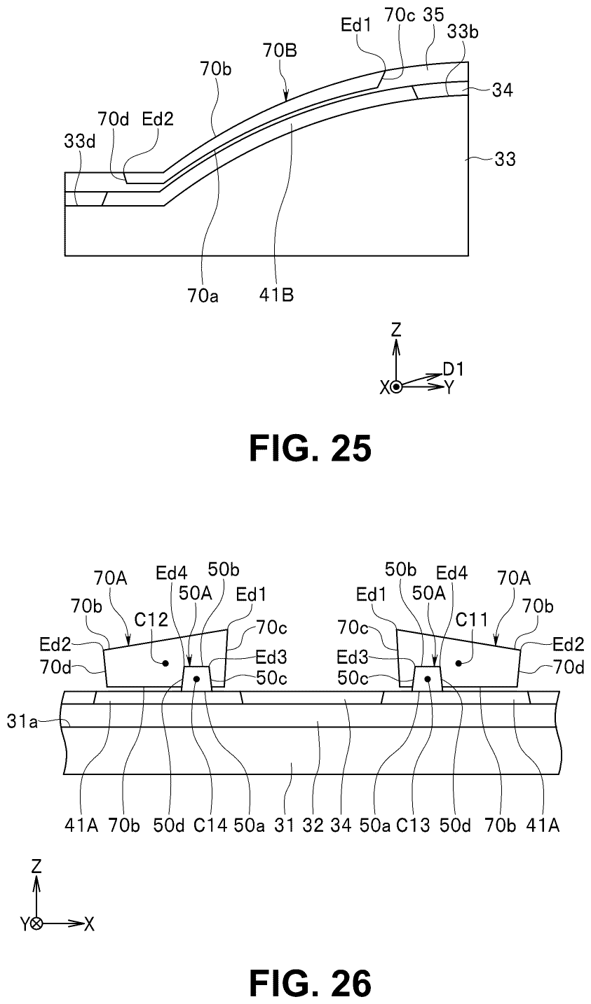

Next, a second example embodiment of the disclosure will be described with reference to FIG. 25. FIG. 25 is a cross-sectional view showing a part of a magnetic sensor in the example embodiment. Note that FIG. 25 shows a cross section parallel to the YZ plane and intersecting the second magnetic field generator 70B. Hereinafter, even when descriptions are made with reference to FIG. 25, features common to the first magnetic field generator 70A and the second magnetic field generator 70B will be described as features of the magnetic field generator 70.

In the example embodiment, the side surface 70d of the magnetic field generator 70 is located above the flat surface 33d of the insulating layer 33. In addition, the second end portion Ed2 of the magnetic field generator 70 is also located above the flat surface 33d. In the example embodiment, a part of the lower electrode 41 may be disposed on the flat surface 33d.

The configuration, operation, and effects of the example embodiment are otherwise the same as those of the first example embodiment.

### Third Example Embodiment

Next, a third example embodiment of the disclosure will be described. A magnetic sensor according to the example embodiment differs from the magnetic sensor 1 according to the first example embodiment in the following points. The first detection circuit 10 (see FIG. 4) in the example embodiment may be configured to detect a component of the target magnetic field in the direction parallel to the X direction and generate at least one first detection signal having a correspondence with the component. The magnetization direction of the magnetization pinned layer 52 in each of the resistor sections R11 and R13 of the first detection circuit 10 may be in the X direction. The magnetization direction of the magnetization pinned layer 52 in each of the resistor sections R12 and R14 of the first detection circuit 10 may be in the —X direction. In addition, the free layer 54 of each of the plurality of first MR elements 50A of the first detection circuit 10 may have a shape anisotropy in which the direction of the magnetization easy axis is parallel to the Y direction. The magnetization direction of the free layer in each of the resistor sections R11 and R12 may be in the Y direction when the target magnetic field is not applied to the first MR element 50A. The magnetization direction of the free layer in each of the resistor sections R13 and R14 in the foregoing case may be in the −Y direction.

In the resistor sections R11 and R12, a bias magnetic field in the Y direction may be applied to the plurality of first MR elements 50A by the plurality of first magnetic field generators 70A. In the resistor sections R13 and R14, a bias magnetic field in the −Y direction may be applied to the plurality of first MR elements 50A by the plurality of first magnetic field generators 70A.

The second detection circuit 20 (see FIG. 5) in the example embodiment may be configured to detect a component of the target magnetic field in the direction parallel to the Y direction and generate at least one second detection signal having a correspondence with the component. The magnetization direction of the magnetization pinned layer 52 in each of the resistor sections R21 and R23 of the second detection circuit 20 may be in the Y direction. The magnetization direction of the magnetization pinned layer 52 in each of the resistor sections R22 and R24 of the second detection circuit 20 may be in the −Y direction. In addition, the free layer 54 of each of the plurality of second MR elements 50B of the second detection circuit 20 may have a shape anisotropy in which the direction of the magnetization easy axis is parallel to the X direction. The magnetization direction of the free layer 54 in each of the resistor sections R21 and R22 may be in the X direction when the target magnetic field is not applied to the second MR element 50B. The magnetization direction of the free layer 54 in each of the resistor sections R23 and R24 in the foregoing case may be in the −X direction.

In the resistor sections R21 and R22, a bias magnetic field in the X direction may be applied to the plurality of second MR elements 50B by the plurality of second magnetic field generators 70B. In the resistor sections R23 and R24, a bias magnetic field in the −X direction may be applied to the plurality of second MR elements 50B by the plurality of second magnetic field generators 70B.

The processor 2 (see FIG. 3) may generate a detection value corresponding to the component of the target magnetic field in the direction parallel to the X direction based on the at least one first detection signal, and generate a detection value corresponding to the component of the target magnetic field in the direction parallel to the Y direction based on the at least one second detection signal.

In the example embodiment, the insulating layer 33 in the first example embodiment is not provided. The plurality of lower electrodes 41A and the plurality of lower electrodes 41B (see FIG. 7 and FIG. 8) are disposed on the insulating layer 32. A top surface of the insulating layer 32 is a plane parallel to the top surface 31a of the substrate 31. Each of the plurality of MR elements 50 is formed so that each of the bottom surface 50a and the top surface 50b of the MR element 50 is parallel to the top surface 31a of the substrate 31.

Next, shapes of and a positional relationship between the first magnetic field generators 70A and the first MR elements 50A in the example embodiment will be described with reference to FIG. 26. FIG. 26 is an explanatory diagram for describing the shapes of and the positional relationship between the first magnetic field generators 70A and the first MR elements 50A. In FIG. 26, the positional relationship between the first magnetic field generators 70A and the first MR elements 50A when viewed in the Y direction is schematically shown. Note that, for convenience, the size of the first magnetic field generator 70A is emphasized compared to that of the first MR element 50A in FIG. 26.

In FIG. 26, two first magnetic field generators 70A and two first MR elements 50A are shown. In FIG. 26, the two first magnetic field generators 70A are disposed so that the side surface 70c of the first magnetic field generator 70A on the right side in FIG. 26 faces the side surface 70c of the first magnetic field generator 70A on the left side in FIG. 26.

In the example embodiment, each of the bottom surface 70a and the top surface 70b of the first magnetic field generator 70A is formed into a plane or a substantially plane shape. Also in the example embodiment, the requirements for the thicknesses T1, T2, and T3 described with reference to FIG. 14 in the first example embodiment are satisfied. In addition, the first end portion Ed1 of the first magnetic field generator 70A is located at a position farther from the reference plane, i.e., the top surface 31a of the substrate 31, than the second end portion Ed2 of the first magnetic field generator 70A. In other words, the distance from the top surface 31a of the substrate 31 to the first end portion Ed1 is greater than the distance from the top surface 31a of the substrate 31 to the second end portion Ed2.

The distance from the top surface 31a of the substrate 31 to the third end portion Ed3 of the first MR element 50A is the same as or approximately the same as the distance from the top surface 31a of the substrate 31 to the fourth end portion Ed4 of the first MR element 50A.

In FIG. 26, the reference sign C11 indicates the center of the first magnetic field generator 70A on the right side in FIG. 26 in the direction parallel to the X direction, the reference sign C12 indicates the center of the first magnetic field generator 70A on the left side in the FIG. 26 in the direction parallel to the X direction, the reference sign C13 indicates the center of the first MR element 50A on the right side in FIG. 26 in the direction parallel to the X direction, and the reference sign C14 indicates the center of the first MR element 50A on the left side in FIG. 26 in the direction parallel to the X direction. As shown in FIG. 26, the distance between the center C11 and the center C12 is greater than the distance between the center C13 and the center C14.

Note that the above description of the shapes and the positional relationship also applies to the second magnetic field generators 70B and the second MR elements 50B. If the first magnetic field generators 70A, the first MR elements 50A, the X direction, and the Y direction in the above description of the shapes and the positional relationship are replaced with the second magnetic field generators 70B, the second MR elements 50B, the Y direction, and the X direction, respectively, the description of the shapes of and the positional relationship between the second magnetic field generators 70B and the second MR elements 50B is obtained.

### Modification Example

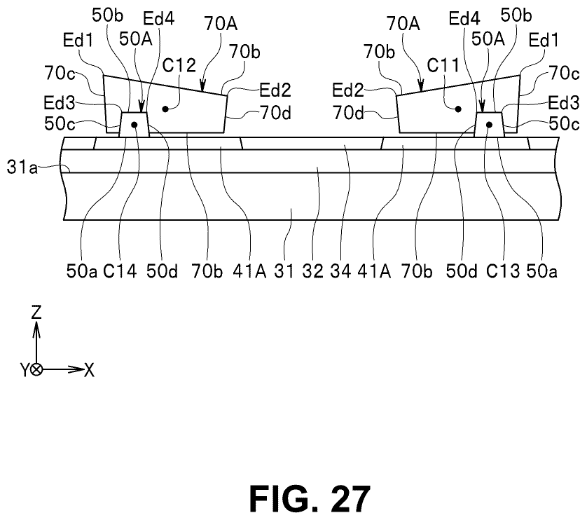

Next, a modification example of the magnetic sensor 101 according to the example embodiment will be described. FIG. 27 is an explanatory diagram for describing the positional relationship between the first magnetic field generators 70A and the first MR elements 50A of the modification example. In FIG. 27, the positional relationship between the first magnetic field generators 70A and the first MR elements 50A when viewed in the Y direction is schematically shown, as in FIG. 26.

In the modification example, two first magnetic field generators 70A are disposed so that the side surface 70d of the first magnetic field generator 70A on the right side in FIG. 27 faces the side surface 70d of the first magnetic field generator 70A on the left side in FIG. 27. As shown in FIG. 27, the distance between the center C11 and the center C12 is smaller than the distance between the center C13 and the center C14.

The above description of the positional relationship applies to the second magnetic field generators 70B and the second MR elements 50B. If the first magnetic field generators 70A in the above description of the positional relationship is replaced with the second magnetic field generators 70B, the description of the positional relationship between the second magnetic field generators 70B and the second MR elements 50B is obtained.

The configuration, operation, and effects of the example embodiment are otherwise the same as those of the first example embodiment.

Note that the disclosure is not limited to each of the foregoing example embodiments, and various modifications may be made thereto. For example, the magnetic sensor 1 of the disclosure may further include a third detection circuit configured to detect a component of the target magnetic field in the direction parallel to the X direction, and generate at least one third detection signal having a correspondence with the component. In this case, the processor 2 may be configured to generate a detection value corresponding to the component of the target magnetic field in the direction parallel to the X direction based on the at least one third detection signal. The third detection circuit may be integrated with the first and second detection circuits 10 and 20, or may be included in a chip separate from the first and second detection circuits 10 and 20.

Furthermore, the MR elements 50 and the magnetic field generators 70 of the disclosure may be aligned along the direction parallel to the Z direction. In such a case, at least a part of the MR element 50 may be disposed to overlap the magnetic field generator 70 when viewed in the Z direction. In addition, in such a case, the direction of the bias magnetic field to be applied to the MR element 50 may be the direction opposite to the magnetization direction of the ferromagnetic portion 73 of the magnetic field generator 70.

As described above, a magnetic sensor according to a first aspect of one embodiment of the disclosure includes: at least one magnetoresistive element; and at least one magnetic field generator including a ferromagnetic portion formed of a ferromagnetic material and an antiferromagnetic portion formed of an antiferromagnetic material and exchange-coupled with the ferromagnetic portion, and configured to generate a bias magnetic field to be applied to the at least one magnetoresistive element. The at least one magnetoresistive element and the at least one magnetic field generator are aligned along a first direction, and are disposed so that at least a part of the at least one magnetoresistive element overlaps the at least one magnetic field generator when viewed in the first direction. The at least one magnetic field generator includes a first end portion and a second end portion located at both ends of the at least one magnetic field generator in a second direction intersecting the first direction, and a first surface connecting the first end portion and the second end portion, has a thickness which is a dimension in a direction perpendicular to the first surface, and includes a first part including the first end portion and a second part including the second end portion. In any given cross section intersecting the at least one magnetic field generator and perpendicular to the first direction, the thickness of the first part is greater than the thickness of the second part. The at least one magnetoresistive element includes a third end portion and a fourth end portion located at both ends of the at least one magnetoresistive element in the second direction, and the at least one magnetoresistive element is disposed so that a distance between the first end portion and the third end portion in the second direction is smaller than a distance between the second end portion and the fourth end portion in the second direction.

The magnetic sensor according to the first aspect of the one embodiment of the disclosure may further includes: a substrate including a top surface; and a support member disposed on the substrate. The at least one magnetoresistive element and the at least one magnetic field generator may be disposed on the support member. The first end portion may be located at a position farther from the top surface than the second end portion. The third end portion may be located at a position farther from the top surface than the fourth end portion.

The magnetic sensor according to the first aspect of the one embodiment of the disclosure may further include: a substrate including a top surface; and a support member disposed on the substrate. The at least one magnetoresistive element and the at least one magnetic field generator may be disposed on the support member. The support member may include a facing surface that faces the at least one magnetoresistive element and the at least one magnetic field generator. In the any given cross section, an inclined angle that the facing surface forms with respect to the top surface may be greater at a second position, which is a position on the facing surface closest to the second end portion, than at a first position, which is a position on the facing surface closest to the first end portion.

The magnetic sensor according to the first aspect of the one embodiment of the disclosure may further include: a substrate including a top surface; and a support member disposed on the substrate. The support member may support the at least one magnetoresistive element and the at least one magnetic field generator, and include a facing surface that faces the at least one magnetoresistive element and the at least one magnetic field generator. The facing surface may include a curved surface part. At least one of the first end portion or the second end portion may be present on the curved surface part.

In the magnetic sensor according to the first aspect of one embodiment of the disclosure, the at least one magnetic field generator may further include a third part present between the first part and the second part. In the any given cross section, the thickness of the third part may be smaller than the thickness of the first part, and may be greater than the thickness of the second part.

In the magnetic sensor according to the first aspect of one embodiment of the disclosure, the at least one magnetoresistive element may include a first magnetoresistive element and a second magnetoresistive element disposed at a distance from each other in the second direction. The at least one magnetic field generator may include a first magnetic field generator and a second magnetic field generator disposed at a distance from each other in the second direction. The first magnetoresistive element may be disposed so that at least a part of the first magnetoresistive element overlaps the first magnetic field generator when viewed in the first direction. The second magnetoresistive element may be disposed so that at least a part of the second magnetoresistive element overlaps the second magnetic field generator when viewed in the first direction. A distance between a center of the first magnetic field generator in the second direction and a center of the second magnetic field generator in the second direction may be different from a distance between a center of the first magnetoresistive element in the second direction and a center of the second magnetoresistive element in the second direction.

A magnetic sensor according to a second aspect of one embodiment of the disclosure includes: a substrate including a top surface; a support member disposed on the substrate; at least one magnetoresistive element disposed on the support member; and at least one magnetic field generator that is disposed on the support member, includes a ferromagnetic portion formed of a ferromagnetic material and an antiferromagnetic portion formed of an antiferromagnetic material and exchange-coupled with the ferromagnetic portion, and is configured to generate a bias magnetic field to be applied to the at least one magnetoresistive element. The at least one magnetoresistive element and the at least one magnetic field generator are aligned along a first direction, and are disposed so that at least a part of the at least one magnetoresistive element overlaps the at least one magnetic field generator when viewed in the first direction. The at least one magnetic field generator includes a first end portion and a second end portion located at both ends of the at least one magnetic field generator in a second direction intersecting the first direction. The at least one magnetoresistive element includes a third end portion and a fourth end portion located at both ends of the at least one magnetoresistive element in the second direction. The first end portion is located at a position farther from the top surface than the second end portion. The third end portion is located at a position farther from the top surface than the fourth end portion. The at least one magnetoresistive element is disposed so that a distance between the first end portion and the third end portion in the second direction is smaller than a distance between the second end portion and the fourth end portion in the second direction.

In the magnetic sensor according to the second aspect of one embodiment of the disclosure, the at least one magnetic field generator may further include a first surface connecting the first end portion and the second end portion, have a thickness which is a dimension in a direction perpendicular to the first surface, and include a first part including the first end portion and a second part including the second end part. In any given cross section intersecting the at least one magnetic field generator and perpendicular to the first direction, the thickness of the first part may be greater than the thickness of the second part.

In the magnetic sensor according to the second aspect of one embodiment of the disclosure, the support member may include a facing surface that faces the at least one magnetoresistive element and the at least one magnetic field generator. In any given cross section intersecting the at least one magnetic field generator and perpendicular to the first direction, an inclined angle that the facing surface forms with respect to the top surface may be greater at a second position, which is a position on the facing surface closest to the second end portion, than at a first position, which is a position on the facing surface closest to the first end portion.

In the magnetic sensor according to the second aspect of one embodiment of the disclosure, the support member may include a facing surface that faces the at least one magnetoresistive element and the at least one magnetic field generator. The facing surface may include a curved surface part. At least one of the first end portion or the second end portion may be present on the curved surface part.

In the magnetic sensor according to the second aspect of one embodiment of the disclosure, the at least one magnetic field generator may further include a first surface connecting the first end portion and the second end portion. A center of the first surface in the second direction may be located at a position closer to the top surface than the first end portion and may be located at a position farther from the top surface than the second end portion.

In the magnetic sensor according to the second aspect of one embodiment of the disclosure, the at least one magnetoresistive element may include a first magnetoresistive element and a second magnetoresistive element disposed at a distance from each other in the second direction. The at least one magnetic field generator may include a first magnetic field generator and a second magnetic field generator disposed at a distance from each other in the second direction. The first magnetoresistive element may be disposed so that at least a part of the first magnetoresistive element overlaps the first magnetic field generator when viewed in the first direction. The second magnetoresistive element may be disposed so that at least a part of the second magnetoresistive element overlaps the second magnetic field generator when viewed in the first direction. A distance between a center of the first magnetic field generator in the second direction and a center of the second magnetic field generator in the second direction may be different from a distance between a center of the first magnetoresistive element in the second direction and a center of the second magnetoresistive element in the second direction.

A magnetic sensor according to a third aspect of one embodiment of the disclosure includes: a substrate including a top surface; a support member disposed on the substrate; at least one magnetoresistive element disposed on the support member; and at least one magnetic field generator that is disposed on the support member, includes a ferromagnetic portion formed of a ferromagnetic material and an antiferromagnetic portion formed of an antiferromagnetic material and exchange-coupled with the ferromagnetic portion, and is configured to generate a bias magnetic field to be applied to the at least one magnetoresistive element. The at least one magnetoresistive element and the at least one magnetic field generator are aligned along a first direction, and are disposed so that at least a part of the at least one magnetoresistive element overlaps the at least one magnetic field generator when viewed in the first direction. The support member includes a facing surface that faces the at least one magnetoresistive element and the at least one magnetic field generator. The at least one magnetic field generator includes a first end portion and a second end portion located at both ends of the at least one magnetic field generator in a second direction intersecting the first direction. In any given cross section intersecting the at least one magnetic field generator and perpendicular to the first direction, an inclined angle that the facing surface forms with respect to the top surface is greater at a second position, which is a position on the facing surface closest to the second end portion, than at a first position, which is a position on the facing surface closest to the first end portion. The at least one magnetoresistive element includes a third end portion and a fourth end portion located at both ends of the at least one magnetoresistive element in the second direction, and the at least one magnetoresistive element is disposed so that a distance between the first end portion and the third end portion in the second direction is smaller than a distance between the second end portion and the fourth end portion in the second direction.

In the magnetic sensor according to the third aspect of one embodiment of the disclosure, the at least one magnetic field generator may further include a first surface connecting the first end portion and the second end portion, have a thickness which is a dimension in a direction perpendicular to the first surface, and include a first part including the first end portion and a second part including the second end part. In the any given cross section, the thickness of the first part may be greater than the thickness of the second part.

In the magnetic sensor according to the third aspect of one embodiment of the disclosure, the first end portion may be located at a position farther from the top surface than the second end portion. The third end portion may be located at a position farther from the top surface than the fourth end portion.

In the magnetic sensor according to the third aspect of one embodiment of the disclosure, the facing surface may include a curved surface part. At least one of the first end portion or the second end portion may be present on the curved surface part.

In the magnetic sensor according to the third aspect of one embodiment of the disclosure, the at least one magnetic field generator may further include a first surface connecting the first end portion and the second end portion. In the any given cross section, the inclined angle may be smaller at the first position than at a third position on the facing surface closest to a center of the first surface in the second direction, and may be greater at the second position than at the third position.

In the magnetic sensor according to the third aspect of one embodiment of the disclosure, the at least one magnetoresistive element may include a first magnetoresistive element and a second magnetoresistive element disposed at a distance from each other in the second direction. The at least one magnetic field generator may include a first magnetic field generator and a second magnetic field generator disposed at a distance from each other in the second direction. The first magnetoresistive element may be disposed so that at least a part of the first magnetoresistive element overlaps the first magnetic field generator when viewed in the first direction. The second magnetoresistive element may be disposed so that at least a part of the second magnetoresistive element overlaps the second magnetic field generator when viewed in the first direction. A distance between a center of the first magnetic field generator in the second direction and a center of the second magnetic field generator in the second direction may be different from a distance between a center of the first magnetoresistive element in the second direction and a center of the second magnetoresistive element in the second direction.

In each of the magnetic sensors of the first to third aspects of the disclosure, the at least one magnetoresistive element is disposed so that the distance between the first end portion and the third end portion is smaller than the distance between the second end portion and the fourth end portion. According to the disclosure, the strength of the bias magnetic field to be applied to the at least one magnetoresistive element can thus be increased.

Obviously, various aspects and modification examples of the disclosure can be implemented in the light of the above teachings. Thus, within the scope of the appended claims and equivalents thereof, the disclosure may be implemented in other embodiments other than the foregoing example embodiments.

1. A magnetic sensor comprising:
at least one magnetoresistive element; and
at least one magnetic field generator including a ferromagnetic portion formed of a ferromagnetic material and an antiferromagnetic portion formed of an antiferromagnetic material and exchange-coupled with the ferromagnetic portion, and configured to generate a bias magnetic field to be applied to the at least one magnetoresistive element, wherein:
the at least one magnetoresistive element and the at least one magnetic field generator are aligned along a first direction, and are disposed so that at least a part of the at least one magnetoresistive element overlaps the at least one magnetic field generator when viewed in the first direction;
the at least one magnetic field generator includes a first end portion and a second end portion located at both ends of the at least one magnetic field generator in a second direction intersecting the first direction, and a first surface connecting the first end portion and the second end portion, the at least one magnetic field generator has a thickness which is a dimension in a direction perpendicular to the first surface, and the at least one magnetic field generator includes a first part including the first end portion and a second part including the second end portion;
in any given cross section intersecting the at least one magnetic field generator and perpendicular to the first direction, the thickness of the first part is greater than the thickness of the second part; and
the at least one magnetoresistive element includes a third end portion and a fourth end portion located at both ends of the at least one magnetoresistive element in the second direction, and the at least one magnetoresistive element is disposed so that a distance between the first end portion and the third end portion in the second direction is smaller than a distance between the second end portion and the fourth end portion in the second direction.

2. The magnetic sensor according to claim 1, further comprising:
a substrate including a top surface; and
a support member disposed on the substrate, wherein:
the at least one magnetoresistive element and the at least one magnetic field generator are disposed on the support member;
the first end portion is located at a position farther from the top surface than the second end portion; and
the third end portion is located at a position farther from the top surface than the fourth end portion.

3. The magnetic sensor according to claim 1, further comprising:
a substrate including a top surface; and
a support member disposed on the substrate, wherein:
the at least one magnetoresistive element and the at least one magnetic field generator are disposed on the support member;
the support member includes a facing surface that faces the at least one magnetoresistive element and the at least one magnetic field generator; and
in the any given cross section, an inclined angle that the facing surface forms with respect to the top surface is greater at a second position, which is a position on the facing surface closest to the second end portion, than at a first position, which is a position on the facing surface closest to the first end portion.

4. The magnetic sensor according to claim 1, further comprising:
a substrate including a top surface; and
a support member disposed on the substrate, wherein:
the support member supports the at least one magnetoresistive element and the at least one magnetic field generator, and includes a facing surface that faces the at least one magnetoresistive element and the at least one magnetic field generator;
the facing surface includes a curved surface part; and
at least one of the first end portion or the second end portion is present on the curved surface part.

5. The magnetic sensor according to claim 1, wherein:
the at least one magnetic field generator further includes a third part present between the first part and the second part; and
in the any given cross section, the thickness of the third part is smaller than the thickness of the first part, and is greater than the thickness of the second part.

6. The magnetic sensor according to claim 1, wherein:
the at least one magnetoresistive element includes a first magnetoresistive element and a second magnetoresistive element disposed at a distance from each other in the second direction;
the at least one magnetic field generator includes a first magnetic field generator and a second magnetic field generator disposed at a distance from each other in the second direction;
the first magnetoresistive element is disposed so that at least a part of the first magnetoresistive element overlaps the first magnetic field generator when viewed in the first direction;
the second magnetoresistive element is disposed so that at least a part of the second magnetoresistive element overlaps the second magnetic field generator when viewed in the first direction; and
a distance between a center of the first magnetic field generator in the second direction and a center of the second magnetic field generator in the second direction is different from a distance between a center of the first magnetoresistive element in the second direction and a center of the second magnetoresistive element in the second direction.

7. A magnetic sensor comprising:
a substrate including a top surface;
a support member disposed on the substrate;
at least one magnetoresistive element disposed on the support member; and
at least one magnetic field generator that is disposed on the support member, includes a ferromagnetic portion formed of a ferromagnetic material and an antiferromagnetic portion formed of an antiferromagnetic material and exchange-coupled with the ferromagnetic portion, and is configured to generate a bias magnetic field to be applied to the at least one magnetoresistive element, wherein:
the at least one magnetoresistive element and the at least one magnetic field generator are aligned along a first direction, and are disposed so that at least a part of the at least one magnetoresistive element overlaps the at least one magnetic field generator when viewed in the first direction;
the at least one magnetic field generator includes a first end portion and a second end portion located at both ends of the at least one magnetic field generator in a second direction intersecting the first direction;
the at least one magnetoresistive element includes a third end portion and a fourth end portion located at both ends of the at least one magnetoresistive element in the second direction;
the first end portion is located at a position farther from the top surface than the second end portion;
the third end portion is located at a position farther from the top surface than the fourth end portion; and
the at least one magnetoresistive element is disposed so that a distance between the first end portion and the third end portion in the second direction is smaller than a distance between the second end portion and the fourth end portion in the second direction.

8. The magnetic sensor according to claim 7, wherein:
the at least one magnetic field generator further includes a first surface connecting the first end portion and the second end portion, has a thickness which is a dimension in a direction perpendicular to the first surface, and includes a first part including the first end portion and a second part including the second end part; and
in any given cross section intersecting the at least one magnetic field generator and perpendicular to the first direction, the thickness of the first part is greater than the thickness of the second part.

9. The magnetic sensor according to claim 7, wherein:
the support member includes a facing surface that faces the at least one magnetoresistive element and the at least one magnetic field generator; and
in any given cross section intersecting the at least one magnetic field generator and perpendicular to the first direction, an inclined angle that the facing surface forms with respect to the top surface is greater at a second position, which is a position on the facing surface closest to the second end portion, than at a first position, which is a position on the facing surface closest to the first end portion.

10. The magnetic sensor according to claim 7, wherein:
the support member includes a facing surface that faces the at least one magnetoresistive element and the at least one magnetic field generator;
the facing surface includes a curved surface part; and
at least one of the first end portion or the second end portion is present on the curved surface part.

11. The magnetic sensor according to claim 7, wherein:
the at least one magnetic field generator further includes a first surface connecting the first end portion and the second end portion; and
a center of the first surface in the second direction is located at a position closer to the top surface than the first end portion and is located at a position farther from the top surface than the second end portion.

12. The magnetic sensor according to claim 7, wherein:
the at least one magnetoresistive element includes a first magnetoresistive element and a second magnetoresistive element disposed at a distance from each other in the second direction;
the at least one magnetic field generator includes a first magnetic field generator and a second magnetic field generator disposed at a distance from each other in the second direction;
the first magnetoresistive element is disposed so that at least a part of the first magnetoresistive element overlaps the first magnetic field generator when viewed in the first direction;
the second magnetoresistive element is disposed so that at least a part of the second magnetoresistive element overlaps the second magnetic field generator when viewed in the first direction; and
a distance between a center of the first magnetic field generator in the second direction and a center of the second magnetic field generator in the second direction is different from a distance between a center of the first magnetoresistive element in the second direction and a center of the second magnetoresistive element in the second direction.

13. A magnetic sensor comprising:
a substrate including a top surface;
a support member disposed on the substrate;
at least one magnetoresistive element disposed on the support member; and
at least one magnetic field generator that is disposed on the support member, includes a ferromagnetic portion formed of a ferromagnetic material and an antiferromagnetic portion formed of an antiferromagnetic material and exchange-coupled with the ferromagnetic portion, and is configured to generate a bias magnetic field to be applied to the at least one magnetoresistive element, wherein:
the at least one magnetoresistive element and the at least one magnetic field generator are aligned along a first direction, and are disposed so that at least a part of the at least one magnetoresistive element overlaps the at least one magnetic field generator when viewed in the first direction;
the support member includes a facing surface that faces the at least one magnetoresistive element and the at least one magnetic field generator;
the at least one magnetic field generator includes a first end portion and a second end portion located at both ends of the at least one magnetic field generator in a second direction intersecting the first direction;
in any given cross section intersecting the at least one magnetic field generator and perpendicular to the first direction, an inclined angle that the facing surface forms with respect to the top surface is greater at a second position, which is a position on the facing surface closest to the second end portion, than at a first position, which is a position on the facing surface closest to the first end portion; and
the at least one magnetoresistive element includes a third end portion and a fourth end portion located at both ends of the at least one magnetoresistive element in the second direction, and the at least one magnetoresistive element is disposed so that a distance between the first end portion and the third end portion in the second direction is smaller than a distance between the second end portion and the fourth end portion in the second direction.

14. The magnetic sensor according to claim 13, wherein:
the at least one magnetic field generator further includes a first surface connecting the first end portion and the second end portion, has a thickness which is a dimension in a direction perpendicular to the first surface, and includes a first part including the first end portion and a second part including the second end part; and
in the any given cross section, the thickness of the first part is greater than the thickness of the second part.

15. The magnetic sensor according to claim 13, wherein:
the first end portion is located at a position farther from the top surface than the second end portion; and
the third end portion is located at a position farther from the top surface than the fourth end portion.

16. The magnetic sensor according to claim 13, wherein:
the facing surface includes a curved surface part; and
at least one of the first end portion or the second end portion is present on the curved surface part.

17. The magnetic sensor according to claim 13, wherein:
the at least one magnetic field generator further includes a first surface connecting the first end portion and the second end portion; and
in the any given cross section, the inclined angle is smaller at the first position than at a third position on the facing surface closest to a center of the first surface in the second direction, and is greater at the second position than at the third position.

18. The magnetic sensor according to claim 13, wherein:
the at least one magnetoresistive element includes a first magnetoresistive element and a second magnetoresistive element disposed at a distance from each other in the second direction;
the at least one magnetic field generator includes a first magnetic field generator and a second magnetic field generator disposed at a distance from each other in the second direction;
the first magnetoresistive element is disposed so that at least a part of the first magnetoresistive element overlaps the first magnetic field generator when viewed in the first direction;
the second magnetoresistive element is disposed so that at least a part of the second magnetoresistive element overlaps the second magnetic field generator when viewed in the first direction; and
a distance between a center of the first magnetic field generator in the second direction and a center of the second magnetic field generator in the second direction is different from a distance between a center of the first magnetoresistive element in the second direction and a center of the second magnetoresistive element in the second direction.
